(19) United States
(12) Patent Application Publication
(10) Pub. No.: US 2025/0112188 A1
(43) Pub. Date: Apr. 3, 2025

(54) FINE-GRAIN INTEGRATION OF RADIO FREQUENCY ANTENNAS, INTERCONNECTS, AND PASSIVES

(71) Applicant: Intel Corporation, Santa Clara, CA (US)

(72) Inventors: Georgios C. Dogiamis, Chandler, AZ (US); Qiang Yu, Saratoga, CA (US); Adel Elsherbini, Chandler, AZ (US); Tushar Kanti Talukdar, Wilsonville, OR (US); Thomas L. Sounart, Chandler, AZ (US)

(73) Assignee: Intel Corporation, Santa Clara, CA (US)

(21) Appl. No.: 18/478,923

(22) Filed: Sep. 29, 2023

(51) Int. Cl. H01L 23/00; H01L 21/683; H01L 23/538; H01L 25/00; H01L 25/18

(52) U.S. Cl. CPC H01L 24/08; H01L 21/6835; H01L 23/5386; H01L 24/03; H01L 24/05; H01L 24/13; H01L 24/32; H01L 24/80; H01L 25/18; H01L 25/50; H01L 2221/68327; H01L 2221/68363; H01L 2221/68368; H01L 2221/68381; H01L 2224/03845; H01L 2224/05573; H01L 2224/05647; H01L 2224/08145; H01L 2224/08225; H01L 2224/13082; H01L 2224/13147; H01L 2224/32145; H01L 2224/80006; H01L 2224/80357; H01L 2224/80379; H01L 2224/80896; H01L 2924/04642; H01L 2924/05442; H01L 2924/059

(57) ABSTRACT

Methods of selectively transferring integrated circuit (IC) components between substrates, and devices and systems formed using the same, are disclosed herein. In one embodiment, a first substrate with a release layer and a layer of IC components over the release layer is received, and a second substrate with one or more adhesive areas is received. The layer of IC components may include one or more antennas, interconnects, inductors, capacitors, or transformers. The first substrate is partially bonded to the second substrate, such that a subset of IC components on the first substrate are bonded to the adhesive areas on the second substrate. The first substrate is then separated from the second substrate, and the subset of IC components bonded to the second substrate are separated from the first substrate and remain on the second substrate.

### BACKGROUND

In semiconductor manufacturing, layer transfer techniques are used to transfer a layer from one substrate to another, typically at wafer-level scale. These techniques require a full layer to be transferred in its entirety regardless of whether the entire layer is needed. As a result, any unneeded portions of a transferred layer must be etched off after the transfer, which increases costs and process complexity.

### BRIEF DESCRIPTION OF THE DRAWINGS

FIGS. 1A-I illustrate an example process flow for selective layer transfers using selective release techniques.

FIGS. 2A-I illustrate an example process flow for selective layer transfers using a blanket laser exposure.

FIGS. 3A-I illustrate an example process flow for selective layer transfers from a singulated donor substrate.

FIGS. 4A-C illustrate an example process flow for selective layer transfers from multiple donor substrates.

FIGS. 5A-F illustrate an example process flow for forming an integrated circuit package using a selective transfer of a passive interposer.

FIGS. 6A-B illustrate an example of a selective layer transfer between wafers.

FIG. 7 illustrates a flowchart for performing selective layer transfers.

FIG. 8 illustrates an example of an integrated circuit (IC) with high-voltage circuitry integrated with CMOS circuitry using selective transfer technology.

FIG. 9 illustrates another example of an IC with a selectively transferred die integrated with CMOS circuitry.

FIG. 10 illustrates another example of an IC with a selectively transferred die integrated with CMOS circuitry.

FIG. 11 illustrates an example of an IC with multiple selectively transferred dies integrated with CMOS circuitry.

FIG. 12 illustrates an example of an IC with a selectively transferred die integrated with gate-all-around (GAA) transistors.

FIGS. 13A-B illustrate an example embodiment of a radio frequency (RF) transceiver system integrated using selective transfer technology.

FIGS. 14 and 15 illustrate example ICs with Group III-V devices and silicon CMOS devices integrated using selective transfer technology.

FIGS. 16A-I and 17A-E illustrate example process flows for integrating Group III-V devices and silicon CMOS devices using selective transfer technology.

FIGS. 18A-C illustrate examples of a passive RF dielet integrated with CMOS circuitry using a hybrid-bonded interconnect.

FIG. 19 illustrates an example of a passive RF dielet integrated with CMOS circuitry on a dielectric mesa.

FIGS. 20A-B illustrate examples of passive RF dielets with different dimensions integrated with CMOS circuitry.

FIGS. 21A-B illustrate examples of dielets integrated with CMOS circuitry among bumps on the surface.

FIGS. 22A-C illustrate examples of dielets integrated with GAA CMOS circuitry on frontside metal and/or backside metal layers.

FIGS. 23A-B illustrate example systems-on-a-chip (SoCs) with input/output (I/O) and wireless components integrated via selective transfer.

FIG. 24 illustrates a flowchart for integrating RF, high-voltage, varactor, Group III-V, and/or passive devices with silicon CMOS devices using selective transfer technology.

FIG. 25 illustrates a top view of a wafer and dies that may be included in a microelectronic assembly.

FIG. 26 illustrates a cross-sectional side view of an integrated circuit device that may be included in a microelectronic assembly.

FIGS. 27A-D illustrate perspective views of example planar, FinFET, gate-all-around, and stacked gate-all-around transistors.

FIG. 28 illustrates a cross-sectional side view of an integrated circuit device assembly that may include a microelectronic assembly.

FIG. 29 illustrates a block diagram of an example electrical device that may include a microelectronic assembly.

### DETAILED DESCRIPTION

### Selective Layer Transfer

In semiconductor manufacturing, layer transfer techniques are used to transfer a layer from one substrate to another, typically at wafer-level scale. Layer transfers are useful for a variety of applications in semiconductor manufacturing, including two-dimensional (2D) material fabrication, Group III-V semiconductors over complementary metal-oxide semiconductors (CMOS), and traditional CMOS applications such as metal-insulator-metal (MIM) devices and thin device and/or interconnect layer transfers. Current layer transfer techniques are limited to full layer transfers, however, which may impact cost and performance when the full layer is not needed. For example, blanket layer transfer techniques, such as ion-cut and laser debonding layer transfers, require a full layer to be transferred in its entirety. As a result, any unneeded areas of the transferred layer must be etched off after the transfer, which results in added cost and process complexity.

Alternatively, pick-and-place techniques can be used to transfer specific dies or chiplets. For example, a chiplet generally refers to an integrated circuit (IC) that contains a well-defined subset of functionality, which is designed to be combined with other chiplets to form a single IC package. To transfer chiplets (e.g., for MIM chiplet integration in a system-on-a-chip (SoC)), chiplet devices are fabricated on a donor substrate (e.g., a wafer or panel), the donor substrate is singulated into chiplets, and the chiplets are then individually attached to a receiver substrate (e.g., an SoC wafer or package) using pick-and-place machines. This adds significant cost due to the extra processing required to singulate the wafer and individually attach the respective chiplet dies. For example, chiplets are generally manufactured on relatively thick substrates to enable them to be handled during the singulation and attach steps without being damaged, and after the attach step, additional processing is performed to thin the chiplets and/or remove the carrier substrate, which further increases the cost and process complexity. In particular, chiplets are typically manufactured on substrates that are over 700 micrometers (μm or microns) thick to provide structural and mechanical stability during fabrication, and after the singulation/attach steps, they may be thinned to approximately 20-100 μm by grinding the backside. However, grinding typically causes chipping along the edges of the chiplet dies. Further, it can be challenging to thin chiplets beyond 20 μm without producing defects. Similarly, chiplets are typically singulated with a die area on the millimeter level scale, as pick-and-place assembly becomes very challenging for chiplets smaller than 1 millimeter (mm) 2.

Integrated circuits can also be manufactured monolithically, where all IC components and interconnections are fabricated sequentially on the same underlying substrate or wafer. Monolithic ICs have various limitations, however, including design limitations due to incompatible processes, lack of flexibility, and low yield.

Accordingly, this disclosure presents selective layer transfer techniques for selectively transferring portions of a layer between substrates, along with devices and systems formed using the same. For example, the described techniques enable select areas of a donor substrate to be transferred to a receiver substrate, which enables the donor substrate to be reused multiple times, while also addressing the limitations described above for blanket layer transfers and pick and place techniques. In particular, the described solution uses a selective release technology on a donor substrate (e.g., wafer, panel, or die) in conjunction with a patterned bonding template on a receiver substrate (e.g., wafer, panel, or die) to allow select areas of a layer on the donor substrate to be transferred to the receiver substrate. For purposes of this disclosure, a layer may refer to one or more layers formed over a substrate, such as an individual layer of material, or a stack of layers that collectively form a layer of IC components (e.g., dies, interconnects, bridges, capacitors, and/or other semiconductor devices). A layer may also include stacked wafers, such as wafer-to-wafer bonded and stacked logic and/or memory wafers. As an example, a donor wafer may include a layer of IC components (e.g., IC dies), and a selective layer transfer may be used to selectively and simultaneously transfer a specific subset of those IC components to a receiver wafer.

The described solution provides various advantages. For example, the described solution enables select areas of a donor wafer to be transferred as opposed to an entire layer, which enables the donor wafer to be reused for multiple products, thus amortizing the cost of expensive devices (e.g., high-density MIM capacitors or high-density passive interposers) across multiple wafers. This solution also eliminates the need to etch away superfluous areas as required by full layer transfers (and as a result, unlike the etched areas after a full layer transfer, selectively transferred areas may not have tapered edges from etching or may have reversed tapering due to the etch to singulate before transfer).

Further, layers of IC components can be selectively transferred at any level of granularity, including full IC dies and packages, interconnects, transistors, resistors, capacitors, partial layers or layer stacks, etc.

This solution also enables areas of ultra-thin layers to be selectively transferred without the added processing and yield loss resulting from the handling challenges of chiplet pick-and-place methods (e.g., singulation, individually attaching each chiplet, post-attach thinning of chiplets). This helps reduce the Z-height of a product (e.g., for formfactor, thermal, and/or power delivery reasons) as well as the overall process complexity. For example, very thin IC dies or chiplets can be formed on any substrate and selectively transferred directly from that substrate. As a result, selectively transferring the dies not only eliminates the need for post-attach thinning, it also enables the dies to be much thinner than dies that are singulated, pick-and-place attached, and then subsequently thinned. In some cases, for example, the described solution may enable transfers of dies with thicknesses ranging from 100 nanometers (nm) to 5 μm or more. Further, since no post-attach thinning is needed, the selectively transferred dies may have no or minimal chipping on the die edges since no grinding is performed, unlike chiplets that are thinned after attachment.

Similarly, this solution supports selective transfers of very small areas on a donor substrate, such as very small dies or chiplets, which is extremely challenging using pick-and-place techniques. In some cases, for example, the described solution may enable transfers of dies (or other IC components) with an area less than 1 mm², such as 100 μm² (10×10 μm), 10,000 μm² (100×100 μm), 810,000 μm² (900×900 μm), etc. (with no limits on the maximum size of an area that can be selectively transferred).

This solution also supports selective transfers of dies with non-standard shapes and designs that are difficult to handle using pick-and-place machines, such as dies with atypical, arbitrary, irregular, or non-convex shapes (e.g., L shape, U shape, shapes with acute angles), dies with high aspect ratios (e.g., 8:1 aspect ratio or higher), dies with holes, and so forth.

Further, this solution has very low topography and supports high surface cleanliness and planarization (e.g., using chemical mechanical polishing (CMP) processing), which makes it compatible with hybrid bonding and fusion bonding processing. Additional advantages are described throughout this disclosure and apparent from the description below.

Accordingly, this solution enables complex IC packages and products to be manufactured by selectively transferring certain components (e.g., active circuitry such as IC dies, passive circuitry) instead of incorporating them using traditional processes, such as: (i) full layer transfers with superfluous areas etched away; (ii) pick-and-place assembly of individual IC components; and/or (iii) monolithic IC fabrication.

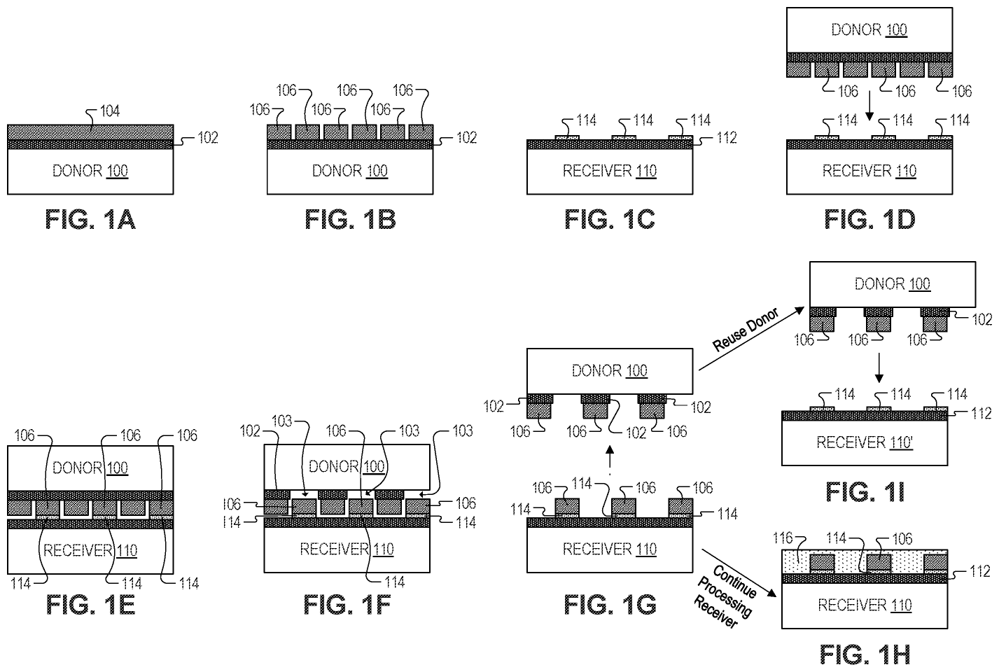

FIGS. 1A-I illustrate an example process flow for selective layer transfers using selective release techniques. In the illustrated example, a layer of integrated circuit (IC) components is selectively transferred from a donor substrate 100 to a receiver substrate 110, as described further below.

In FIG. 1A, a release layer 102 is formed over a carrier substrate, which is referred to as the donor substrate 100. The release layer 102 is a temporary bonding and debonding layer for the layer 104 to be selectively transferred. In some embodiments, the release layer 102 may include one or more layers and/or materials capable of providing adhesion to the donor substrate 100 and/or absorbing energy from a laser (e.g., laser beams), such as lossy dielectric and/or thin metal layer(s) that provide adhesion and absorb/reflect infrared (IR) light, organic polymer layer(s) (e.g., polyimides) that provide adhesion and absorb visible or ultraviolet (UV) light, and/or patterned dielectric layer(s) with anchors to provide residual adhesion (e.g., after the metal layer is ablated by an IR laser).

The layer 104 to be selectively transferred is formed over the release layer 102 of the donor substrate 100, such as by fabricating the layer 104 directly or blanket transferring the layer 104. The selective transfer layer 104 may include one or more layers of material, such as a single layer of material or a stack of layers that collectively form a layer of IC components (e.g., full IC dies, chiplets, interconnects, bridges, capacitors, transistors, and/or other semiconductor devices). In some embodiments, for example, the selective transfer layer 104 may be a prefabricated semiconductor wafer containing unsingulated integrated circuit (IC) dies, which is blanket transferred to the release layer 102 on a donor wafer 100.

In FIG. 1B, the selective transfer layer 104 is diced over the donor substrate 100—without dicing through the donor substrate 100—to partially singulate the IC components 106 in the layer 104, using techniques such as etching, reactive ion etching (RIE), plasma dicing, mechanical sawing, etc. In some embodiments, the release layer 102 may also be singulated (e.g. diced or etched) along with the transfer layer 104.

In FIG. 1C, a release layer 112 is optionally formed over another carrier substrate, which is referred to as the receiver substrate 110. For example, the release layer 112 may be formed over the receiver substrate 110 if the selectively transferred IC components 106 will be subsequently debonded from the receiver substrate 110 after the transfer. Otherwise, if the selectively transferred IC components 106 will remain on the receiver substrate 110 after the transfer, the release layer 112 on the receiver 110 may be omitted.

Next, a bonding template 114 is formed on the surface of the receiver substrate 110 (e.g., above the release layer 112, if included). The bonding template 114 includes a pattern of bonding features or adhesive areas 114 that enable specific areas of the donor substrate 100 to be selectively transferred to the receiver substrate 110. For example, the positions of the bonding features 114 on the receiver substrate 110 correspond to the areas or IC components 106 on the donor substrate 100 that will be transferred to the receiver substrate 110.

In some embodiments, for example, the bonding features 114 may include “island” or “mesa” structures that are similar in size to the target areas to be transferred from the donor substrate 100. For example, each island or mesa structure 114 may be a raised structure on the surface of the receiver substrate 110 with a similar footprint (e.g., shape/surface area) as a corresponding IC component 106 on the donor substrate 100. In other embodiments, the mesas 114 may be replaced by lithographically or additively manufactured surface treatments that enhance the adhesion in the target areas of the receiver substrate 110 (e.g., the areas where the mesas 114 are shown) and prevents adhesion in the other areas, including, without limitation, surface topography variations, use of materials with high and/or low adhesion, treatments using hydrophobic materials and/or self-assembled monolayers (SAMs), and/or surface activation techniques, among other examples.

In various embodiments, these bonding features 114 may be made of dielectric materials, conductive materials (e.g., metal), or both, depending on whether electrical connections are needed between the bonded IC components 106 and the receiver substrate 110. For example, the bonding features 114 may be blanket dielectric structures with no electrical contacts, or they may be dielectric structures with electrical/conductive contacts through them (e.g., hybrid bonding pads) if electrical connections are needed through the bonding interface.

In FIG. 1D, the donor and receiver substrates 100, 110 are brought into contact with each other with their top surfaces aligned face to face, such that the target IC components 106 on the donor 100 are aligned with corresponding bonding features 114 on the receiver 110.

In FIG. 1E, the donor and receiver substrates 100, 110 are partially bonded together. For example, the areas of the receiver substrate 110 with protruding surface features or “mesas” 114 are bonded to corresponding areas of the donor substrate 110 with the target IC components 106, while other areas of the donor and receiver substrates 100, 110 remain unbonded. In some embodiments, for example, this is controlled through the height of the bonding protrusions 114 to prevent unwanted contact between areas that are not to be transferred. As previously mentioned, this can also be controlled through surface treatment of the different areas to enable good adhesion in the target areas (e.g., where the mesas 114 are shown) and prevent or reduce adhesion in other areas.

In FIG. 1F, the IC components 106 bonded to the receiver 110 are selectively debonded from the donor 100 using selective release techniques, such as IR debonding, selective visible or ultraviolet (UV) laser exposure, etc. For example, areas 103 of the release layer 102 where those IC components 106 are bonded to the donor 100 may be selectively removed or ablated using a laser, such as an IR or UV laser, which forms gaps or voids 103 in the release layer 102 and causes those IC components 106 to be released from the donor 100.

In FIG. 1G, the donor and receiver substrates 100, 110 are mechanically separated from each other. At this point, the IC components 106 that were selectively bonded to the receiver 110 (e.g., via the bonding structures 114) and debonded from the donor 100 remain on the receiver 110 and are separated from the donor 100. All other IC components 106 that were not bonded to the receiver 110 remain on the donor 100.

In FIG. 1H, the receiver substrate 110 is now ready for continued processing, such as dielectric fill 116 around the transferred IC components 106, planarization, selectively transferring or pick-and-place attaching additional IC dies or other IC components, via formation, formation of interconnect/metallization layers, attaching a structural substrate, debonding the receiver substrate (e.g., via the optional receiver release layer 112), and/or any other processing required for the finished product (e.g., an IC package).

In FIG. 1I, the donor substrate 100 is then reused to transfer the remaining IC components 106 (e.g., the remaining areas of the selectively transferred layer 104) to a new receiver substrate 110′. The donor substrate 100 can continue being reused in this manner until all IC components 106, or the entire layer 104, have been selectively transferred to any number of receiver substrates 110.

It should be appreciated that the illustrated process flow for selective layer transfers is merely presented as an example and many other process variations are also possible. For example, the donor and receiver substrates 100, 110 may be wafers, panels, IC packages, chiplets, dies, or any combination thereof (e.g., for transfers from wafer to panel, chiplet to wafer, etc.). Moreover, each substrate 100, 110 may be made of a variety of materials, including, without limitation, inorganic materials such as silicon, silicon on insulator (SOI), quartz, glass, and/or Group III-V materials, organic materials such as IR or UV transparent epoxies, and so forth.

The materials used in the release layers 102, 112 may vary depending on the type of release or debonding technology used. For example, for infrared (IR) laser debonding, the release layers 102, 112 may include one or more materials capable of absorbing and/or reflecting infrared (IR) light, such as a thin metal layer or multiple metal layers (e.g., aluminum (Al), tungsten (W), copper (Cu), titanium (Ti), titanium nitride (TiN), tantalum (Ta), tantalum nitride (TaN), niobium (Nb), niobium nitride (NbN)). For ultraviolet (UV) laser debonding, the release layers 102, 112 may include one or more materials capable of absorbing UV light (e.g., a wide range of organic polymers, including, but not limited to, polyimides). In some embodiments, the release layers 102, 112 may additionally or alternatively include one or more layers of dielectric materials (e.g., silicon dioxide (SiO₂), silicon nitride (Si₃N₄), silicon oxynitride (SiON), silicon carbide (SiC), silicon carbon nitride (SiCN), silicon oxycarbon nitride (SiOCN), aluminum oxide (Al₂O₃), low-k dielectrics such as carbon-doped oxide (CDO) or porous silicon dioxide (SiO₂), titanium dioxide (TiO₂), tantalum oxide (Ta₂O₅)), which may be used to buffer laser ablation and thermal energy, control thin film interference or adhesion, and/or provide residual adhesion after other materials and/or layers in the release layers 102, 112 are weakened, removed, and/or ablated by a laser.

The number of layers 104 on the donor substrate 100, the arrangement/structure of the layers 104, the materials in each layer 104, and the type of IC components 106 formed in those layers 104 may vary.

The adhesive areas or bonding features 114 on the receiver substrate 110 may be formed using any suitable surface treatments or other techniques to control the level of adhesion in different areas, including, without limitation, surface topography variations (e.g., mesas, recesses), use of materials with high and/or low adhesion, treatments using hydrophobic materials and/or self-assembled monolayers (SAMs), and/or surface activation techniques, among other examples. Moreover, the bonding features or adhesive areas 114 on the receiver substrate 110 may vary in size, shape, height, topography, pattern, and materials. For example, the bonding features 114 may be formed using inorganic dielectrics such as silicon dioxide (SiO₂), silicon nitride (Si₃N₄), silicon oxy nitride (SiON), and/or silicon carbon nitride (SiCN), organic dielectrics such as photoresists and adhesives, conductive materials such as metals, and combinations thereof.

The donor and receiver substrates 100, 110 may be (partially) bonded using any suitable bonding techniques, including, without limitation, hybrid bonding, fusion bonding, and adhesive bonding. The donor and receiver substrates 100, 110 may be debonded or released using any suitable debonding techniques, including, without limitation, IR and UV laser debonding. Further, there may be additional cleaning steps to reuse the donor substrate 100 before or after each selective layer transfer to a receiver substrate 110.

Further, in some embodiments, additional bonding and/or alignment features may be included at the wafer level and/or die level (e.g., on the donor dies, donor wafer, receiver wafer, and/or final product). For example, the donor and/or receiver wafer may include ridge or cross structures to facilitate bonding, such as a single ridge (e.g., a line or strip of dielectric material) extending across and/or through the center of the wafer, or multiple orthogonal ridges forming a cross-like pattern. Alignment features for wafers, die-lets, and/or die arrays may also be included to facilitate bonds with proper alignment. Further, multiple dies may be connected by small (e.g., dielectric) bridges to help them collectively bond and transfer together. For example, if some of the bridge-connected dies successfully bond to the receiver, the bridges may help others bond as well. Thus, these inter-die bridges may be present on the donor before the transfer, and on the receiver and final product after the transfer.

Further, in some cases, the debonding process may cause some unique damage or delamination near the edge and/or on the back of the dies, which does not impact process performance but may be indicative of this solution being used.

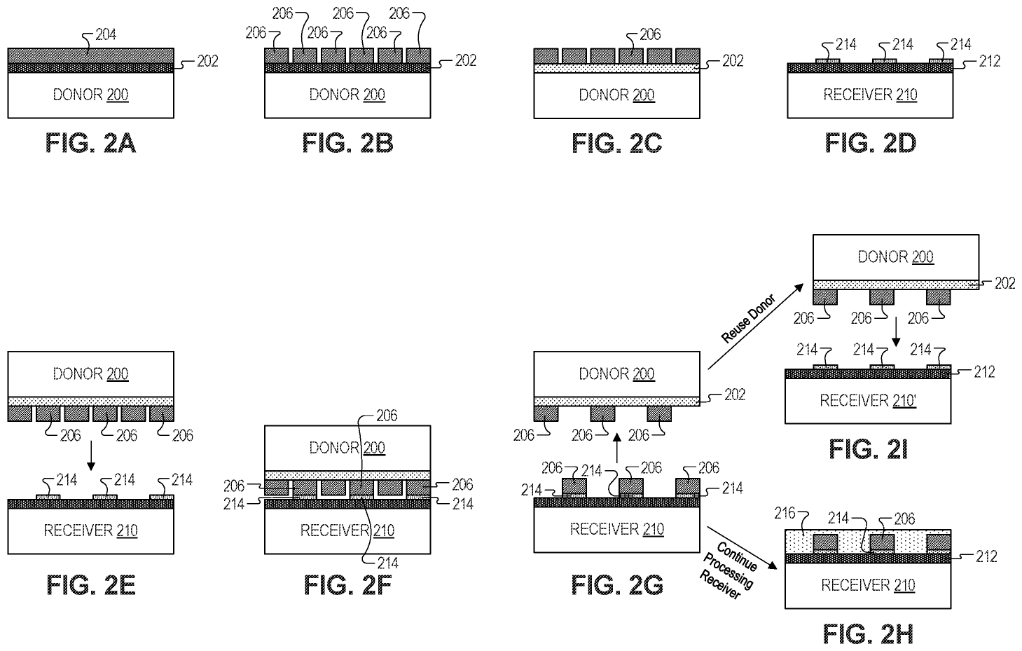

FIGS. 2A-I illustrate an example process flow for selective layer transfers using a blanket laser exposure. In the illustrated example, a layer 204 of integrated circuit (IC) components 206 is selectively transferred from a donor substrate 200 to a receiver substrate 210. Prior to the transfer, however, the entire release layer 202 on the donor 200 is mechanically weakened (e.g., using IR laser, visible light laser, UV laser, chemical etching, and/or thermal techniques), which may also be referred to as a partial release. In this manner, after the target IC components 206 on the donor 200 are bonded to the receiver 210, they can be fully released from the donor 200 by mechanically separating the donor 200 from the receiver 210. In some cases, this may result in a simplified and faster bond/debond flow compared to the bond/selective release/debond flow of FIGS. 1A-I. Alternatively, rather than using blanket laser exposure, the respective materials used in the donor release layer 202 and the receiver bonding template 214 may be selected such that the bond to the donor 200 is weaker than the subsequently formed bond to the receiver 210.

In FIG. 2A, a release layer 202 is formed over a donor substrate 200. The layer 204 to be selectively transferred is formed over the release layer 202, such as by fabricating the layer 204 directly or blanket transferring the layer 204. In some embodiments, the selective transfer layer 204 may be a layer of IC components (e.g., IC dies, chiplets, interconnects, bridges, capacitors, transistors, and/or other semiconductor devices).

In FIG. 2B, the selective transfer layer 204 is diced over the donor substrate 200—without dicing through the donor substrate 200—to partially singulate the IC components 206 in the layer 204.

In FIG. 2C, blanket laser exposure is performed on the donor release layer 202 to weaken the entire release layer 202 prior to the transfer. In some embodiments, for example, blanket laser exposure may be performed using laser (e.g., IR or UV laser exposure), chemical, and/or thermal techniques. In this manner, the weakened release layer 202 has lower bond energy, which results in a partial release of the IC components 206 bonded to that layer 202.

In FIG. 2D, a release layer 212 is optionally formed over a receiver substrate 210. For example, if the selectively transferred IC components 206 will be subsequently debonded from the receiver substrate 210 after the transfer, a release layer 212 may be formed over the receiver 210; otherwise, the release layer 212 on the receiver 210 may be omitted.

Next, a bonding template 214 is formed on the surface of the receiver substrate 210 (e.g., above the release layer 212, if included). The bonding template 214 includes a pattern of bonding features or adhesive areas 214, such as mesas, that enable specific areas of the donor substrate 200 to be selectively transferred to the receiver substrate 210. In various embodiments, however, any suitable surface treatments or other techniques may be used to control the level of adhesion on different areas of the receiver substrate 210 (e.g., to form adhesive and non-adhesive areas for selective transfers), including, without limitation, surface topography variations (e.g., mesas, recesses), use of materials with high and/or low adhesion, treatments using hydrophobic materials and/or self-assembled monolayers (SAMs), and/or surface activation techniques, among other examples.

In FIG. 2E, the donor and receiver substrates 200, 210 are brought into contact with each other with their top surfaces aligned face to face, such that the target IC components 206 on the donor 200 are aligned with corresponding bonding features 214 on the receiver 210.

In FIG. 2F, the donor and receiver substrates 200, 210 are partially bonded together, where the areas of the donor 200 with the target IC components 206 are bonded to the areas on the receiver 210 with bonding mesas 214.

In FIG. 2G, the donor and receiver substrates 200, 210 are mechanically separated from each other. At this point, the IC components 206 that were selectively bonded to the receiver 210 (e.g., via the bonding mesas 214) remain on the receiver 210 and are debonded/separated from the donor 200 due to the blanket weakening of the donor release layer 202. All other IC components 206 that were not bonded to the receiver 210 remain on the donor 200.

Alternatively, in some embodiments, instead of (or in addition to) performing blanket laser exposure in FIG. 2C, the respective materials used in the donor release layer 202 and the receiver bonding template 214 may be selected such that the target IC components 206 will have a stronger bond to the receiver 210 than the donor 200. In this manner, when the donor 200 and receiver 210 are mechanically separated, the target IC components 206 will debond from the donor 200 and remain on the receiver 210 due to the disparity in bond strength.

In FIG. 2H, the receiver substrate 210 is ready for continued processing, such as dielectric fill 216 around the transferred IC components 206, planarization, selectively transferring or pick-and-place attaching additional IC dies or other IC components, via formation, formation of interconnect/metallization layers, attaching a structural substrate, debonding the receiver substrate (e.g., via the optional receiver release layer 212), and/or any other processing required for the finished product (e.g., an IC package).

In FIG. 2I, the donor substrate 200 is then reused to transfer the remaining IC components 206 (e.g., the remaining areas of the selectively transferred layer 204) to a new receiver substrate 210′. The donor substrate 200 can continue being reused in this manner until all IC components 206, or the entire layer 204, have been selectively transferred to any number of receiver substrates 210.

Elements labeled with reference numerals in FIGS. 2A-I may be similar to those having similar reference numerals in FIGS. 1A-I. Further, it should be appreciated that the illustrated process flow for selective layer transfers is merely presented as an example and many other process variations are also possible, including, but not limited to, the process variations described throughout this disclosure.

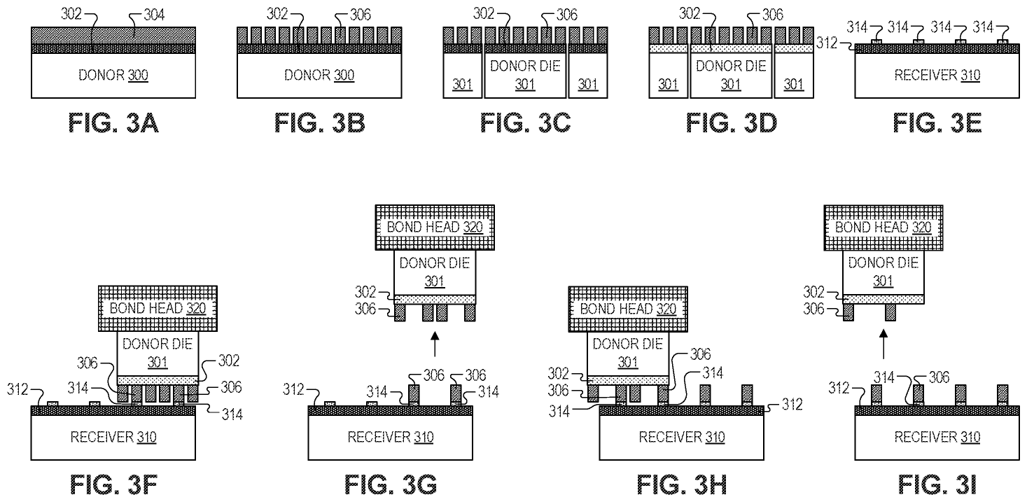

FIGS. 3A-I illustrate an example process flow for selective layer transfers from a singulated donor substrate 300. In some cases, for example, if the percentage of transferred integrated circuit (IC) components 306 is relatively small for each selective layer transfer, it may be easier and more cost efficient to dice the donor substrate 300 and perform the transfers from singulated donor dies 301 that contain smaller subsets of IC components 306 from the original donor substrate 300. Accordingly, in the illustrated example, a donor substrate 300 with a layer 304 of IC components 306 is diced, and the resulting layer of IC components 306 on a singulated donor die 301 is selectively transferred to a receiver substrate 310. In this manner, the transfers are performed at the donor die level rather than the wafer or panel level.

In FIG. 3A, a release layer 302 is formed over a donor substrate 300. The layer 304 to be selectively transferred is formed over the release layer 302, such as by fabricating the layer 304 directly or blanket transferring the layer 304. In some embodiments, the selective transfer layer 304 may be a layer of IC components (e.g., IC dies, chiplets, interconnects, bridges, capacitors, transistors, and/or other semiconductor devices).

In FIG. 3B, the selective transfer layer 304 is diced over the donor substrate 300—without dicing through the donor substrate 300—to partially singulate the IC components 306 in the layer 304. In some embodiments, the release layer 302 may also be singulated (e.g., diced or etched) along with the transfer layer 306.

In FIG. 3C, the donor substrate 300 is diced into singulated donor dies 301 that each contain a subset of the IC components 306 from the original donor substrate 300. For example, each donor die 301 may include one or more IC components 306 from the layer 304 on the original donor substrate 300.

In FIG. 3D, either blanket laser exposure (as shown) or a selective laser release is performed on the donor release layer 302 to weaken the entire release layer 302 prior to the transfer (e.g., using IR/UV laser exposure or thermal techniques), thus partially releasing the IC components 306 from the donor dies 301.

In FIG. 3E, a release layer 312 is optionally formed over a receiver substrate 310 (e.g., in the event the selectively transferred IC components 306 will be subsequently debonded from the receiver substrate 310 after the transfer). Next, a bonding template 314 is formed on the surface of the receiver substrate 310 (e.g., above the release layer 312, if included). The bonding template 314 includes a pattern of bonding features or adhesive areas 314, such as mesas, that enable specific areas of a donor die 301 to be selectively transferred to the receiver substrate 310. In various embodiments, however, any suitable surface treatments or other techniques may be used to control the level of adhesion on different areas of the receiver substrate 310 (e.g., to form adhesive and non-adhesive areas for selective transfers), including, without limitation, surface topography variations (e.g., mesas, recesses), use of materials with high and/or low adhesion, treatments using hydrophobic materials and/or self-assembled monolayers (SAMs), and/or surface activation techniques, among other examples.

In FIG. 3F, a bond head 320 is used to pick up one of the donor dies 301 and place it face down on the receiver substrate 310 such that the target IC components 306 on the donor die 301 are aligned with the corresponding bonding mesas 314 on the receiver substrate 310. The donor die 301 and receiver substrate 310 are then partially bonded together (e.g., die-to-wafer bond) with the target IC components 306 bonded to the receiver bonding mesas 314.

In FIG. 3G, the bond head 320 lifts up and mechanically separates the donor die 301 from the receiver substrate 310. At this point, the IC components 306 that were selectively bonded to the receiver 310 (e.g., via the bonding mesas 314) remain on the receiver 310 and are debonded/separated from the donor die 301 (e.g., die-to-wafer debond) due to the blanket weakening of the donor release layer 302. All other IC components 306 that were not bonded to the receiver substrate 310 remain on the donor die 301.

Alternatively, in some embodiments, instead of (or in addition to) performing blanket laser exposure in FIG. 3D, the target IC components 306 may be selectively released (e.g., as described with respect to FIG. 1F), or the donor release layer 302 and receiver bonding template 314 may be formed with materials having different bonding strengths such that the target IC components 306 will have a stronger bond to the receiver substrate 310 than the donor die 301.

In FIG. 3H and FIG. 3I, the bond head 320 steps and repeats. For example, the bond head 320 moves to a new position and repeats the process of FIG. 3F and FIG. 3G, respectively, to selectively transfer another group of IC components 306 from the donor die 301 to other areas of the receiver substrate 310.

The process may repeat in this manner until all IC components 306 on the donor die 301 have been transferred. At that point, the bond head 320 may pick up another donor die 301 and continue transferring IC components 306 from the new donor die 301 to the same or different receiver substrate 310.

After all transfers to the receiver substrate 310 are complete, the receiver 310 may be ready for continued processing, such as dielectric fill around the transferred IC components 306, planarization, selectively transferring or pick-and-place attaching additional IC dies or other IC components, via formation, formation of interconnect/metallization layers, attaching a structural substrate, debonding the receiver substrate (e.g., via the optional receiver release layer 312), and/or any other processing required for the finished product (e.g., an IC package).

Elements labeled with reference numerals in FIGS. 3A-I may be similar to those having similar reference numerals in FIGS. 1A-I. Further, it should be appreciated that the illustrated process flow for selective layer transfers is merely presented as an example and many other process variations are also possible, including, but not limited to, the process variations described throughout this disclosure.

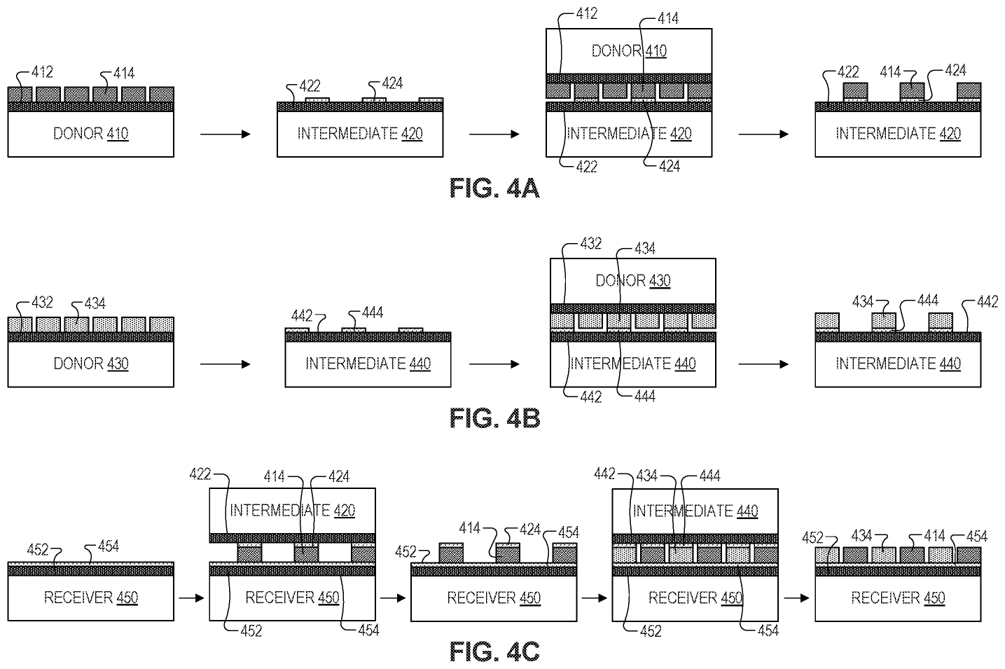

FIGS. 4A-C illustrate an example process flow for selective layer transfers from multiple donor substrates. In the illustrated example, integrated circuit (IC) components 414, 434 from multiple donor substrates 410, 430 are selectively transferred to a receiver substrate 450 using intermediate carrier substrates 420, 440. In some embodiments, the respective donors 410, 430 may have different types of IC components 414, 434, such as different types of IC dies or chiplets. In this manner, selective layer transfers can be used to transfer multiple types of IC components, such as different types of dies or chiplets, to the same receiver substrate 450. While the illustrated example depicts selective transfers from two types of donor substrates 410, 430 (e.g., with two types of types of IC components 414, 434), any number of donor substrates with any type of IC dies or other components are possible (including different die sizes).

In FIG. 4A, a layer of IC components 414 is selectively transferred from a first donor substrate 410 to an intermediate carrier substrate 420 (e.g., using any of the selective transfer flows described throughout the disclosure). For example, a release layer 412 is formed over the donor substrate 410. The layer 414 to be selectively transferred is then formed over the release layer 412 (e.g., by fabricating the layer 414 directly or blanket transferring the layer 414 from a wafer to the donor carrier 410) and diced into partially singulated IC components 414. Separately, a release layer 422 is formed over an intermediate carrier/receiver substrate 420, and a bonding template 424 is formed on the surface of the intermediate carrier 420 (e.g., above the release layer 422). The donor 410 and intermediate carrier 420 are then partially bonded together (e.g., with the target IC components 414 on the donor 410 bonded to the bonding features or adhesive areas 424 on the intermediate carrier 420). The donor 410 and intermediate carrier 420 are then debonded and separated from each other using any of the techniques described throughout this disclosure (e.g., selective release, blanket laser exposure, etc.). As a result, the target IC components 414 are debonded/separated from the donor 410 and remain on the intermediate carrier 420.

In FIG. 4B, another layer of IC components 434 is selectively transferred from a second donor substrate 430 to another intermediate carrier substrate 440 (e.g., using any of the selective transfer flows described throughout the disclosure). For example, a release layer 432 is formed over the donor substrate 430. The layer 434 to be selectively transferred is then formed over the release layer 432 (e.g., by fabricating the layer 434 directly or blanket transferring the layer 434 from a wafer to the donor carrier 430) and diced into partially singulated IC components 434. Separately, a release layer 442 is formed over an intermediate carrier/receiver substrate 440, and a bonding template 444 is formed on the surface of the intermediate carrier 440 (e.g., above the release layer 442). The donor 430 and intermediate carrier 440 are then partially bonded together (e.g., with the target IC components 434 on the donor 430 bonded to the bonding features or adhesive areas 444 on the intermediate carrier 440). The donor 430 and intermediate carrier 440 are then debonded and separated from each other using any of the techniques described throughout this disclosure (e.g., selective release, blanket laser exposure, etc.). As a result, the target IC components 434 are debonded/separated from the donor 430 and remain on the intermediate carrier 440.

In FIG. 4C, the IC components 414, 434 on both intermediate carriers 420, 440 are selectively transferred to a receiver substrate 450 (e.g., using any of the selective transfer flows described throughout the disclosure). For example, a release layer 452 is optionally formed over the receiver substrate 450 (e.g., in the event the selectively transferred IC components 414, 434 will be subsequently debonded from the receiver substrate 450 after the transfer). A bonding layer 454 (e.g., with adhesive areas/bonding features) is then formed on the surface of the receiver 450 (e.g., above the release layer 452, if included). Next, the IC components 414 on the first intermediate carrier 420 are selectively transferred to the receiver substrate 450 (e.g., using any of the selective transfer flows described throughout the disclosure). Finally, the IC components 434 on the second intermediate carrier 440 are selectively transferred to the receiver substrate 450 (e.g., using any of the selective transfer flows described throughout the disclosure).

Additional processing may then be performed on the receiver substrate 450, such as cleaning steps (e.g., removing the leftover bonding structures 424, 444 from the transferred IC components 414, 434), dielectric fill around the transferred IC components 414, 434, planarization, selectively transferring or pick-and-place attaching additional IC dies or other IC components, via formation, formation of interconnect/metallization layers, attaching a structural substrate, debonding the receiver substrate (e.g., via the optional receiver release layer 452), and/or any other processing required for the finished product (e.g., an IC package).

It should be appreciated that the illustrated process flow for selective layer transfers is merely presented as an example and many other process variations are also possible, including, but not limited to, the process variations described throughout this disclosure.

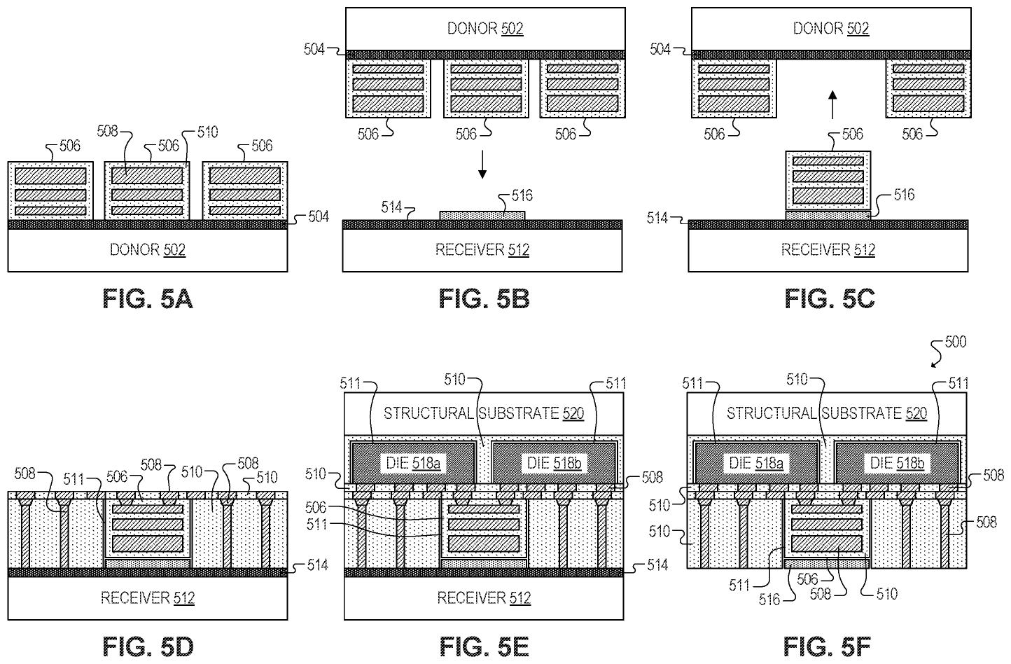

FIGS. 5A-F illustrate an example process flow for forming an integrated circuit (IC) package 500 with a selectively transferred passive interposer 506. Selective transfers can be used for a variety of applications, including transfers of active components (e.g., IC dies, transistors, diodes) and passive components (e.g., interconnects, metal-insulator-metal (MIM) chiplets, resistors, capacitors, inductors, transformers). In the illustrated example, the process flow is used to form an IC package 500 with a selectively-transferred low-cost passive interposer 506. For example, interposers 506 with high-density die-to-die (D2D) links 508 are created on a donor wafer 502 and then selectively transferred to a receiver wafer 512, which enables the same donor wafer 502 to be reused multiple times and amortizes the cost of the interconnect devices across multiple receiver wafers 512. In some embodiments, other components of the IC package 500 may also be selectively transferred, such as the IC dies 518a-b. Selective transfers can also be used for other applications, including, without limitation, transfers of photonic/optical components, and localized transfers of Group III-V semiconductors for radio frequency (RF) and high-power devices.

In FIG. 5A, repeated D2D interconnect patterns 506 are created on a release layer 504 of the donor substrate 502, and the resulting D2D interconnects are partially singulated (e.g., diced to, but not through, the donor substrate 502). The D2D interconnects 506 include high-density interconnect links 508 separated by dielectric layers 510.

In FIG. 5B, a transfer template 516 for a selective transfer is created on a release layer 514 of a receiver/carrier substrate 512. The transfer template 516 includes a dielectric bonding protrusion 516, referred to as a mesa, on the surface of the receiver substrate 512. In various embodiments, however, any suitable surface treatments or other techniques may be used to control the level of adhesion on different areas of the receiver substrate 512 (e.g., to form adhesive and non-adhesive areas for selective transfers), including, without limitation, surface topography variations (e.g., mesas, recesses), use of materials with high and/or low adhesion, treatments using hydrophobic materials and/or self-assembled monolayers (SAMs), and/or surface activation techniques, among other examples. Further, in various embodiments, any number of buildup layers may be formed on the receiver substrate 512 prior to forming the templated connection pedestal or mesa 516 for the selective transfer.

The bonding mesa 516 is used to selectively transfer a D2D interconnect 506 from the donor 502 to the receiver 512 (e.g., using any of the selective transfer flows described throughout this disclosure). For example, the donor 502 and receiver 512 are aligned face to face, stacked, and then partially bonded together such that one of the D2D interconnects 506 on the donor 502 is bonded to the bonding mesa 516 on the receiver 512.

In FIG. 5C, the D2D interconnect 506 bonded to the receiver mesa 516 is debonded and/or released from the donor release layer 504 using any of the techniques described herein (e.g., selective release, blanket laser exposure, formation of bonds with strength disparities), and the donor 502 and receiver 512 are mechanically separated. As a result, the transferred D2D interconnect 506 is separated from the donor 502 and remains on the receiver 512.

In FIG. 5D, additional processing is performed to form the remaining interconnect, including dielectric (e.g., oxide) fill 510 and planarization, interconnect 508 patterning/metallization (e.g., formation of through-dielectric vias (TDVs) 508, top metal contacts 508 such as hybrid bonding pads, dielectric layers 510), and so forth.

Notably, since the D2D interposer 506 was selectively transferred while the surrounding dielectric layers 510 were fabricated directly on the receiver 512, there is a seam 511 between the transferred D2D interposer 506 and the surrounding layers 510, as shown in FIG. 5D. In general, this type of seam or transition may be present around selectively transferred components of any type since they are not formed contemporaneously with the surrounding layers.

In FIG. 5E, multiple IC dies 518a-b are attached to the top metal pads 508 (e.g., via hybrid bonding), the area around the dies 518a-b is filled with dielectric material 510 (e.g., oxide) and planarized, and a structural substrate 520 is attached (e.g., a structural silicon wafer).

The dies 518a-b may be attached using standard assembly techniques, such as pick and place, or using the selective transfer techniques described herein (e.g., similar to the transferred D2D interconnect 506).

If the dies 518a-b are attached using pick-and-place assembly, they are typically formed on a thick substrate for handling purposes and then subsequently thinned after the attach.

If the dies 518a-b are selectively transferred, however, they can be formed on—and transferred directly from—a very thin substrate. As a result, selectively transferring the dies 518a-b not only eliminates the need for post-attach thinning, it also enables the dies 518a-b to be much thinner than dies that are pick-and-place attached and subsequently thinned. Further, if the dies 518a-b are selectively transferred, there may be a seam 511 between the dies 518a-b and portions of the layers 510 surrounding the dies 518a-b, similar to the seam 511 shown around the transferred D2D interconnect 506, as described above. Moreover, because the dies 518a-b are selectively transferred, they can be different types of dies, formed on separate pieces of substrate material (e.g., separate wafers or panels) using separate processes, and then selectively transferred to the same layer of an IC device 500.

In FIG. 5F, the receiver 512 is debonded and released from the release layer 514 (e.g., using any of the techniques described herein, such as IR or UV laser ablation).

At this point, the IC package 500 may be complete, or alternatively, additional processing may be performed. For example, if the processing is performed at the wafer or panel level, the resulting IC packages 500 on the structural substrate 520 may be singulated.

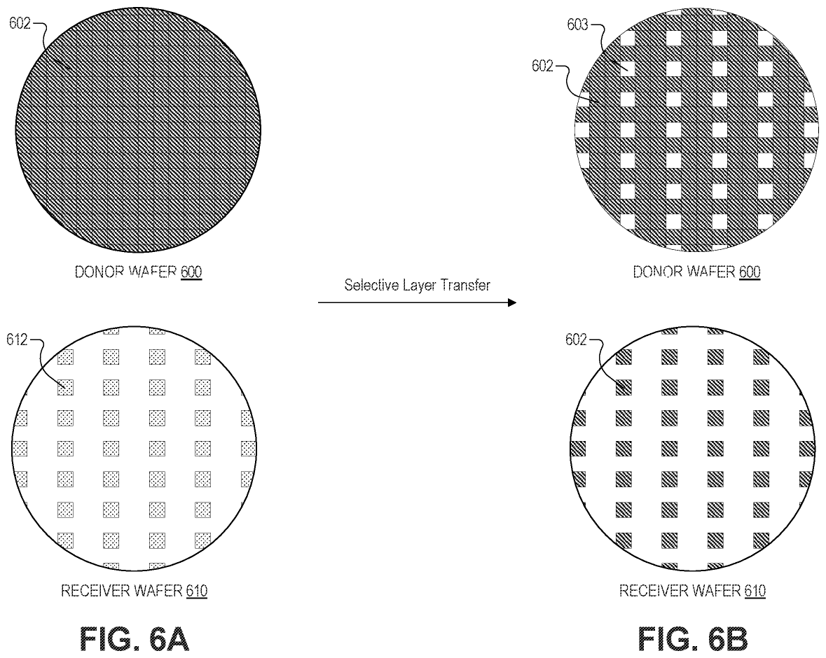

FIGS. 6A-B illustrate an example of a selective layer transfer between donor and receiver wafers 600, 610. In particular, FIG. 6A shows the wafers 600, 610 prior to the transfer, while FIG. 6B shows the wafers 600, 610 after the transfer. In the illustrated example, non-contiguous areas of the donor wafer 600 are selectively transferred to non-contiguous positions on the receiver wafer 610. In other embodiments, however, the target areas on the donor 600 and the destination areas on the receiver 610 may be partially contiguous or fully contiguous.

As shown in FIG. 6A, prior to the transfer, the donor wafer 600 includes a layer of integrated circuit (IC) components 602 (e.g., dies, chiplets, interconnects, capacitors, transistors, etc.), which may be partially singulated (e.g., diced down to, but not through, the underlying wafer 600). The receiver wafer 610 includes adhesive areas 612 patterned in non-contiguous positions on the surface (also referred to as a bonding template), which is where the target IC components 602 from the donor 600 will be transferred. In some embodiments, for example, the adhesive areas 612 may be raised structures or protrusions (referred to as “mesas”) patterned on the surface of the receiver 612. Moreover, in some embodiments, the adhesive areas 612 on the receiver 610 may have a similar footprint as the target IC components 602 on the donor 600. In various embodiments, however, any suitable surface treatments or other techniques may be used to control the level of adhesion on different areas of the receiver substrate 610 (e.g., to form adhesive and non-adhesive areas for selective transfers), including, without limitation, surface topography variations (e.g., mesas, recesses), use of materials with high and/or low adhesion, treatments using hydrophobic materials and/or self-assembled monolayers (SAMs), and/or surface activation techniques, among other examples.

As shown in FIG. 6B, after the transfer, the target IC components 602 have been transferred from the donor wafer 600 to the receiver wafer 610. As a result, the donor wafer 600 includes empty areas 603 where the transferred IC components 602 were located, while the receiver wafer 610 includes the transferred IC components 602 in the positions where the adhesive areas 612 were patterned. In particular, individual IC components 602 from the donor wafer 600 are now bonded to individual adhesive areas 612 on the receiver wafer 610.

While the illustrated example depicts a selective transfer between two wafers, selective transfers can be performed between panels or other substrates of any shape or size, including substrates with mismatched shapes and sizes.

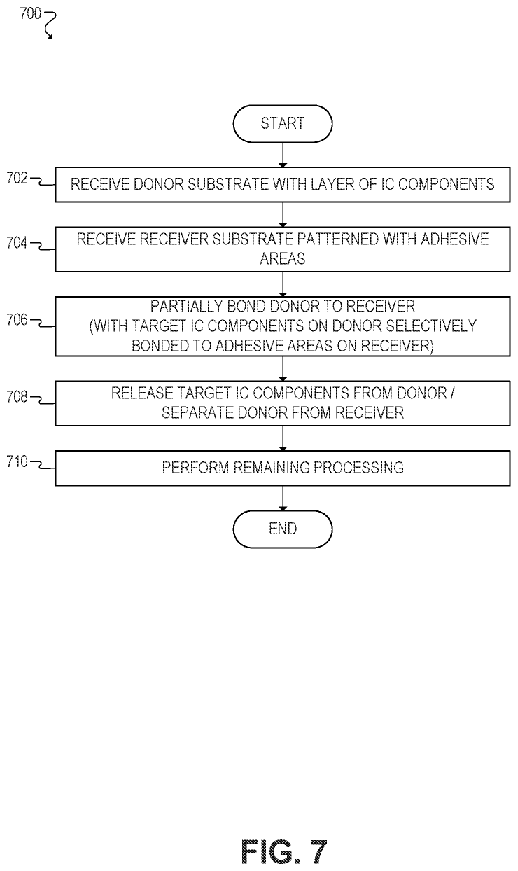

FIG. 7 illustrates a flowchart 700 for performing selective layer transfers. It will be appreciated in light of the present disclosure that the illustrated process flow is only one example methodology for performing selective layer transfers. Moreover, the steps of the illustrated process flow may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metal-organic chemical vapor deposition (MOCVD), molecular beam epitaxy (MBE), atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The flowchart begins at block 702 by receiving a first substrate with a layer of integrated circuit (IC) components, which may be referred to as the donor substrate. In some embodiments, the donor substrate may include a base substrate, a release layer over the base substrate, and a (partially singulated) layer of IC components over the release layer.

In some embodiments, the donor substrate may be formed by receiving the base substrate, forming the release layer over the base substrate, forming the layer of IC components over the release layer (e.g., by fabricating or transferring the layer of IC components over the release layer), and partially singulating the layer of IC components (e.g., by dicing through the layer of IC components without dicing through the base substrate).

In various embodiments, the layer of IC components may include one or more IC dies, interconnects, transistors, diodes, resistors, capacitors, inductors, transformers, RF and/or high-voltage components (e.g., thick gate oxide transistors, Group III-V transistors, varactors, electrostatic discharge (ESD) protection devices, RF antennas, RF interconnects, and other passives RF devices such as capacitors, inductors, and transformers), optical/opto-electrical components, and/or any other active or passive circuitry or components.

The base substrate may be made of one or more materials that include elements such as silicon (Si), oxygen (O), carbon (C), hydrogen (H), and/or Group III-V elements (e.g., aluminum (Al), gallium (Ga), indium (In), nitrogen (N), phosphorus (P), arsenic (As), antimony (Sb)), including, without limitation, silicon (Si), silicon dioxide (silica or SiO₂), silicon on insulator (SOI), quartz, glass, Group III-V materials (e.g., gallium nitride (GaN), aluminum gallium nitride (AlGaN), gallium arsenide (GaAs), indium gallium arsenide (InGaAs), indium phosphide (InP)), and epoxies/resins (e.g., IR or UV transparent epoxies).

The release layer may include one or more layers of varying materials depending on the type of release or debonding technology used. For example, for IR laser debonding, the release layer may include one or more layers of material(s) capable of absorbing and/or reflecting infrared (IR) electromagnetic radiation, such as a thin metal layer or multiple metal layers (e.g., aluminum (Al), tungsten (W), copper (Cu), titanium (Ti), titanium nitride (TiN), tantalum (Ta), tantalum nitride (TaN), niobium (Nb), niobium nitride (NbN)). For UV laser debonding, the release layer may include one or more layers of material(s) capable of absorbing ultraviolet (UV) electromagnetic radiation (e.g., organic polymers such as polyimides). In some embodiments, the release layer may additionally or alternatively include one or more layers of dielectric materials to buffer laser ablation and thermal energy, control thin film interference or adhesion, and/or provide residual adhesion after other materials and/or layers in the release layers are weakened, removed, and/or ablated by a laser (e.g., silicon dioxide (SiO₂), silicon nitride (Si₃N₄), silicon oxynitride (SiON), silicon carbide (SiC), silicon carbon nitride (SiCN), silicon oxycarbon nitride (SiOCN), aluminum oxide (Al₂O₃), low-k dielectrics such as carbon-doped oxide (CDO) or porous silicon dioxide (SiO₂), titanium dioxide (TiO₂), tantalum oxide (Ta₂O₅)). Thus, in some embodiments, the release layer(s) may be made of one or more materials that include elements such as aluminum (Al), tungsten (W), copper (Cu), titanium (Ti), tantalum (Ta), niobium (Nb), silicon (Si), oxygen (O), nitrogen (N), hydrogen (H), and carbon (C), including, without limitation, any of the materials referenced above.

The flowchart then proceeds to block 704 to receive a second substrate with one or more adhesive areas, which may be referred to as the receiver substrate. In some embodiments, the receiver substrate may include a base substrate patterned with one or more adhesive areas on the surface, such as a layer of raised bonding structures or “mesas” over the base substrate. The receiver substrate may also optionally include a release layer over the base substrate (e.g., to enable the base substrate to be subsequently debonded after the transfer) and/or one or more additional buildup layers and/or IC components.

In some embodiments, the receiver substrate may be formed by receiving the base substrate, optionally forming a release layer over the base substrate, optionally forming additional buildup layers and/or IC components over the base substrate (e.g., over the optional release layer, if included), and forming the adhesive areas (e.g., bonding structures) on the surface of the receiver substrate (e.g., over the previously referenced layers, if included). In some embodiments, the base substrate and the optional release layer of the receiver may be made of any of the materials referenced above for the base substrate and the release layer of the donor, respectively.

In some embodiments, the adhesive areas may include mesa structures with similar footprints as the corresponding IC components to be transferred from the donor (although, in some cases, the mesas may be slightly larger or smaller than the IC components to accommodate alignment and manufacturing tolerances). The mesa structures may be made of varying materials depending on the type of bond and/or whether electrical connections are needed through the bond interface for the subsequently bonded IC components (e.g., dielectric material, metal, or both). For example, the mesa structures may include blanket dielectric structures with no conductive contacts (e.g., for dielectric-to-dielectric bonds), dielectric structures with conductive contacts (e.g., for hybrid dielectric and metal bonds), and/or conductive contacts by themselves (e.g., for metal-to-metal bonds). Thus, in some embodiments, the mesa structures may be made of one or more materials that include elements such as silicon (Si), oxygen (O), hydrogen (H), nitrogen (N), carbon©, aluminum (Al), tungsten (W), copper (Cu), titanium (Ti), tantalum (Ta), including, without limitation, inorganic dielectrics such as silicon dioxide (SiO₂), silicon nitride (Si₃N₄), and/or silicon carbon nitride (SiCN), organic dielectrics such as photoresists and adhesives, and/or conductive materials such as metals and alloys (e.g., any of the foregoing metal elements and/or compounds/alloys thereof).

In various embodiments, however, any suitable technique(s) may be used to control the level of adhesion on different areas of the receiver substrate. For example, a variety of surface treatments (e.g., lithographically or additively manufactured) can be used to enhance and/or reduce adhesion in select areas of the receiver substrate, including, without limitation, modifying the surface topography (e.g., raised vs. recessed areas, smooth vs. rough areas), use of materials with high and/or low adhesion (e.g., forming layers with adhesive and non-adhesive materials in select areas), treatments using hydrophobic materials and/or self-assembled monolayers (SAMs), and/or surface activation techniques (e.g., plasma or wet activation), among other examples.

For example, the surface topography of the receiver substrate may be modified (e.g., using techniques such as deposition, lithography, etching, roughening) to form areas with different levels of adhesion, such as raised (e.g., adhesive) and recessed (e.g., non-adhesive) areas, smooth (e.g., adhesive) and rough (e.g., non-adhesive) areas, etc.

As another example, the surface of the receiver substrate may be patterned with materials having high and/or low adhesion in select areas. For example, a layer patterned with different areas of adhesive and non-adhesive materials may be formed on the receiver substrate. In some embodiments, the adhesive material may include silicon dioxide (SiO₂) or silicon carbon nitride (SiCN) to promote strong oxide fusion bonds, silicon carbide (SiC) to provide lower thermal contact resistance compared to SiO₂ or SiCN, and/or metal to form electrical connections. Further, in some embodiments, the non-adhesive material may include silicon nitride (Si₃N₄) to form weak or no bonds.

As another example, treatments using hydrophobic materials and/or self-assembled monolayers (SAMs) may be used to enhance and/or reduce adhesion in select areas of the receiver substrate (e.g., using a SAM treatment to create monolayers with high and/or low adhesion in select areas). In some embodiments, the hydrophobic material may include a SAM material such as an alkyl or fluoroalkyl silane (e.g., ODS, FDTS), a thiol (e.g., hexadecane thiol), a phosphonic acid (e.g., octadecyl or perfluorooctane phosphonic acid), or an alkanoic acid (e.g., heptadecanoic acid). However, non-SAM based materials or films may also be used. In some embodiments, the hydrophobic material may include a thin polymer film such as a siloxane (e.g., PDMS and derivatives, HMDSO), a silazane (HMDS), a polyolefin (e.g., PP), or a fluorinated polymer (e.g., PTFE, PFPE, PFDA, C₄F₈ plasma polymerized films, etc.). Other hydrophobic materials may be used in other embodiments.

As another example, surface activation techniques may be used to enhance and/or reduce adhesion in select areas of the receiver substrate, including, without limitation, plasma or wet activation.

The flowchart then proceeds to block 706 to partially bond the donor substrate to the receiver substrate (e.g., face to face), such that one or more target IC components on the donor substrate are selectively bonded to the one or more adhesive areas on the receiver substrate. The donor and receiver substrates may be partially bonded using any suitable bonding techniques, including, without limitation, hybrid bonding, fusion bonding, and/or adhesive bonding.

The flowchart then proceeds to block 708 to release the target IC components from the donor substrate and separate the donor substrate from the receiver substrate. In this manner, when the donor and receiver substrates are separated, the target IC components are separated from the donor substrate and remain on the receiver substrate.

In some embodiments, the donor and receiver substates may be debonded/separated from each other by releasing, at least partially, the target IC components from the release layer of the donor substrate and then mechanically separating the donor and receiver substrates. For example, in some embodiments, the release layer may be exposed to electromagnetic radiation from a laser to weaken or ablate some or all areas and/or underlying materials of the release layer. For example, the target IC components may be fully released from the donor substrate by selectively debonding them from the donor release layer using a laser (e.g., an IR or UV laser), or alternatively, the target IC components may be partially released from the donor substrate by weakening the donor release layer using a laser (e.g., an IR or UV laser). After fully or partially releasing the target IC components from the donor, the donor and receiver substrates are mechanically separated, and post separation, the target IC components remain bonded to the receiver and are no longer on the donor.

Alternatively, or additionally, the donor release layer and the receiver bonding structures may be formed with respective materials that have disparate bond strengths-such that the target IC components have a stronger bond to the receiver than the donor-thus causing the target IC components to debond from the donor and remain on the receiver when the donor and receiver are mechanically separated.

The flowchart then proceeds to block 710 to perform any remaining processing, such as dielectric filling and planarization, attaching additional IC dies or components (e.g., via selective transfers or pick-and-place assembly), forming interconnects (e.g., vias, traces), attaching a structural substrate, debonding the receiver base substrate (e.g., via the optional receiver release layer), and/or any other processing required for the finished product (e.g., an IC package, device, system, etc.).

The completed product may include a variety of components and circuitry (some of which may have been selectively transferred), including electrical components (e.g., electronic integrated circuits (EICs), processors, XPUs, controllers, memory), optical components (e.g., optical interfaces, photonic integrated circuits (PICs), optical connectors, fibers), and/or radio frequency (RF) or high-voltage components (e.g., high-voltage electrostatic discharge (ESD) devices, power amplifiers (PAs), low noise amplifiers (LNAs), voltage controlled oscillators (VCOs), surface acoustic wave (SAW)/bulk acoustic wave (BAW) devices or filters, bandpass filters (BPFs), intermediate-frequency (IF) amplifiers, frequency synthesizers, mixers, digital-to-analog converters (DACs), analog-to-digital converters (ADCs), thick oxide devices (e.g., transistors with a thick gate oxide), Group III-V devices/chiplets (e.g., transistors made of one or more Group III-V materials), passive RF devices such as interconnects, antennas, and inductors).

Further, in some embodiments, the resulting IC package or product may be electrically coupled to a circuit board and/or incorporated into an electronic device or system (e.g., with other electronic components).

At this point, the flowchart may be complete. In some embodiments, however, the flowchart may restart and/or certain blocks may be repeated. For example, in some embodiments, the flowchart may restart at block 702 to continue performing selective transfers.

### Fine-Grain Integration of RF and High-Voltage Devices

As semiconductor devices continue scaling down in size, the operating voltage of transistors is typically reduced (e.g., below 1 volt (V) for most fin field-effect transistor (FinFET) and gate-all-around (GAA) transistor nodes) due to several reliability-related failing mechanisms, such as oxide breakdown, hot carrier injection, bias temperature instability, etc. However, high voltage is still desired for a variety of applications, such as input/output (I/O), power management integrated circuits (PMIC), power amplifiers (PAS), high-voltage electrostatic discharge (ESD) protection devices (e.g., for ESD protection/control), and other radio frequency (RF) devices, among other examples. In some cases, high-voltage applications may be implemented using thick oxide devices (e.g., semiconductor devices/transistors with relatively thick gate oxides for handling high supply voltages, such as more than 1.5 volts (V)), but that requires additional masks and fabrication processes, along with a transition area between thick oxide and thin oxide devices due to different gate/poly pitches (e.g., distances between gates). Moreover, in GAA nodes, certain devices such as varactors (e.g., voltage-controlled capacitors) cannot be fabricated efficiently, as GAA transistors have no body control terminal. Thus, while varactors can be implemented using GAA transistors, the tuning range and quality factor (Q) is low. Thus, these approaches have various disadvantages, including higher costs and lower efficiency. For example, adding additional device variants in the fabrication process increases costs and development time, and the additional devices also complicate design rules and make the technology harder to use, resulting in low ease of use.

Further, while 2.5D and 3D integration can be used to assemble chiplets from different technologies in the same package (e.g., a mixture of silicon (Si) from different nodes, Group III-V nodes, acoustic resonators/microelectromechanical systems (MEMS), etc.), these technologies do not support fine-grain disaggregation and integration down to the device/intellectual property (IP) level. For example, standard integration processes (e.g., pick-and-place) typically require chiplets to have a minimum area of several square millimeters (mm²), which is insufficient for device-level fine-grain disaggregation/integration of chiplets with dimensions on micrometer-level scale (e.g., below 1 mm², such as 10×10 μm, 100×100 μm, 900×900 μm, etc.).

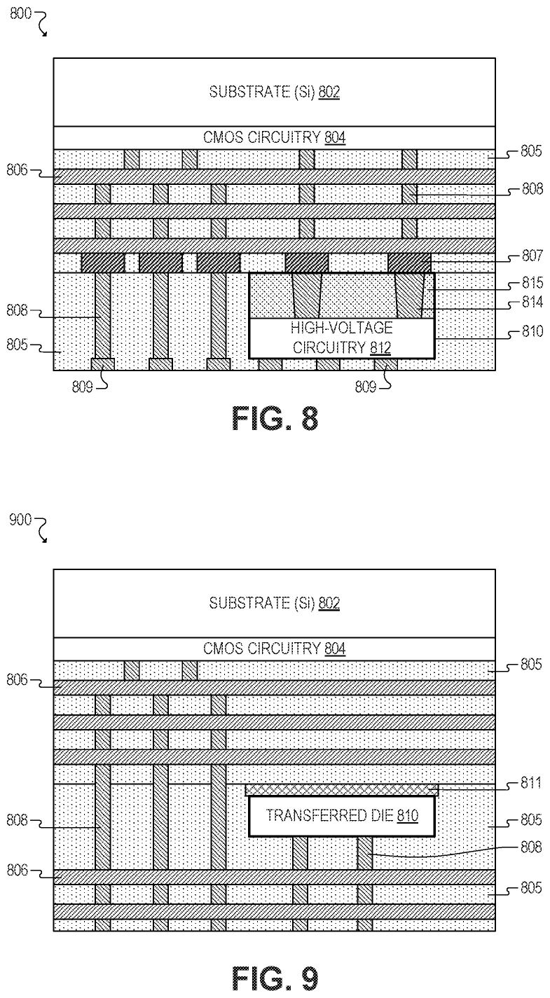

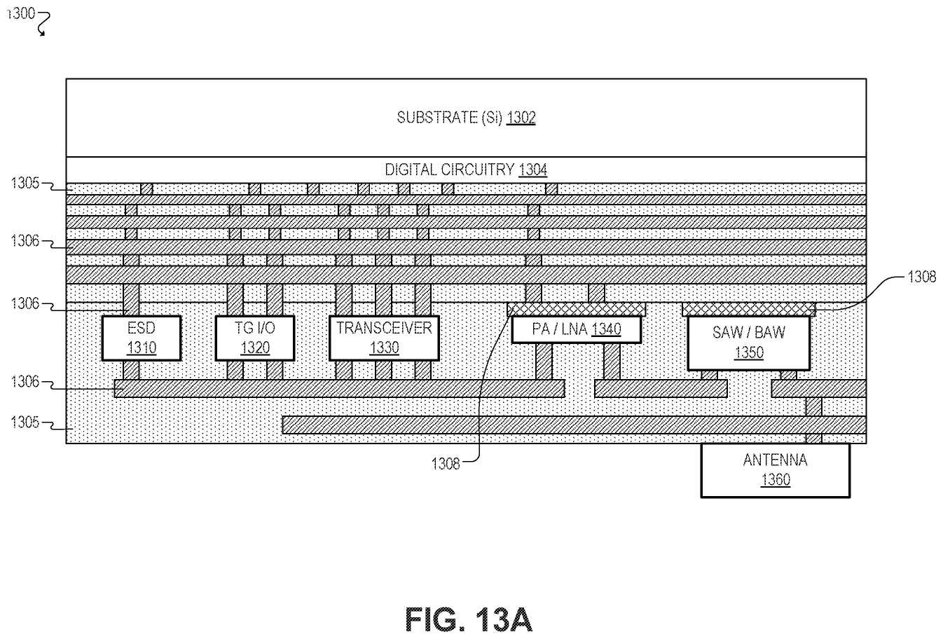

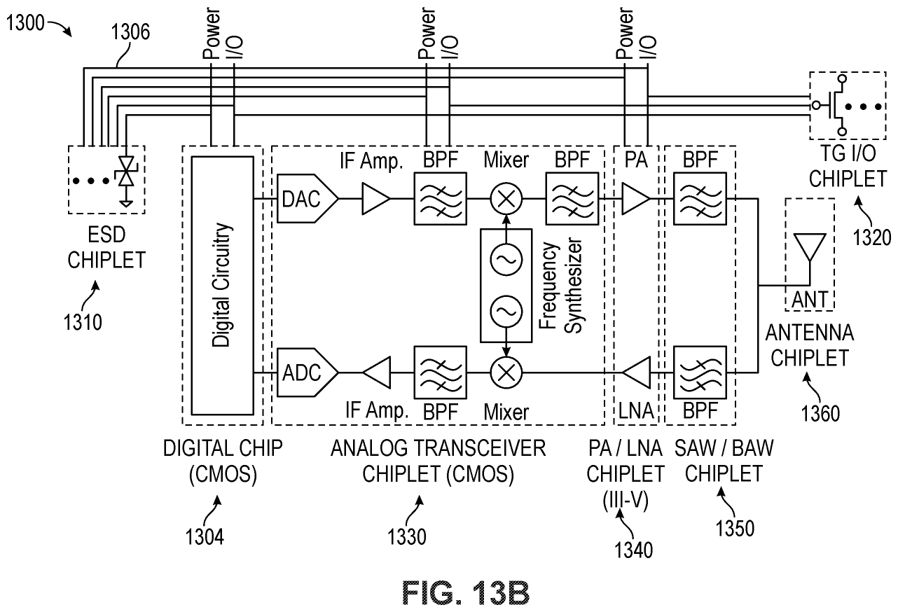

Accordingly, this disclosure presents methods for fine-grain integration of high-voltage (e.g., RF) devices and varactors using selective transfer technology, along with devices and systems formed using the same. In some embodiments, selective transfer technology may be used to enable fine-grain integration of such devices (e.g., thick gate oxide transistors, Group III-V (e.g., GaN/InP/GaAs) transistors, high-voltage ESD devices, I/O devices, PMICs, PAs, high-Q varactor devices, etc.) on top of a semiconductor substrate (e.g., wafer or die) fabricated using an advanced complementary metal-oxide-semiconductor (CMOS) process. For example, integration of thick oxide transistors, Group III-V transistors, varactors, and high voltage ESDs is shown in FIGS. 8-12, and integration of a full RF transceiver system is shown in FIGS. 13A-B. This solution provides an efficient technology development process in terms of both time and cost, while also enabling architectures that support optimized selections of semiconductor processes down to the device level.

The described solution provides various advantages. For example, high-voltage components and varactors can be fabricated in a separate process from CMOS devices and then selectively transferred to the same substrate, and as a result, they do not need to be compatible with advanced CMOS node fabrication flows (e.g., temperature, materials, tools, etc.). In addition to lower technology development costs, design rules and process design kits (PDKs) are simplified for all employed processes, which makes the technology easy to use and efficient to design with.

FIG. 8 illustrates an example embodiment of an integrated circuit (IC) 800 with high-voltage circuitry integrated with CMOS circuitry using selective transfer technology. In the illustrated embodiment, CMOS circuitry 804 (e.g., CMOS logic/devices/transistors) is fabricated on a silicon substrate 802 (e.g., using an advanced CMOS process), along with multiple inter-layer dielectric (ILD) layers 805, routing layers 806 (e.g., interconnect/conductive traces), vias 808, and hybrid-bonded interconnect (HBI) pads 807. Further, an IC die 810 with high-voltage circuitry 812 is fabricated separately (e.g., using another technology-specific process) and then integrated with the CMOS circuitry 804 via selective transfer (e.g., as described with respect to FIGS. 1-7 above and throughout this disclosure). As shown, the IC 800 is flipped relative to the orientation in which it was fabricated (e.g., for flip chip packaging).

In the illustrated embodiment, the IC die 810 includes high-voltage circuitry 812, an interconnect layer 814 (e.g., conductive traces/vias), and an ILD layer 815. In some embodiments, the high-voltage circuitry 812 may include thick gate oxide transistors, Group III-V transistors, varactors, and/or high-voltage electrostatic discharge (ESD) devices, which may be used for high-voltage applications, input/output (I/O) circuitry, and frequency synthesizers (e.g., voltage controlled oscillators (VCOs)), among other examples. Moreover, the IC die 810 is selectively transferred from a donor substrate and hybrid bonded to the HBI pads 807 below the routing layers 806, thus interconnecting the high-voltage circuitry 812 with the CMOS circuitry 804 via a hybrid-bonded interconnect.

Further, high-aspect-ratio through-dielectric vias (TDVs) 808 are formed around the transferred die 810, and both the TDVs 808 and the transferred die 810 are electrically coupled to conductive pads 809 on the bottom of IC 800 to provide external connectivity for the CMOS circuitry 804 and the high-voltage circuitry 812 (e.g., connectivity to the IC package or other components (not shown)).

FIG. 9 illustrates another example embodiment of an integrated circuit (IC) 900 with a selectively transferred IC die 810 integrated with CMOS circuitry 804. In the illustrated embodiment, IC 900 is similar to IC 800, but the transferred die 810 is transferred only once in the middle of the metal stack 806 on a raised mesa 811 (e.g., a raised dielectric, hybrid bonding, or metallic structure) using the selective transfer process (hence orientation of vias may be of the same orientation as the base wafer).

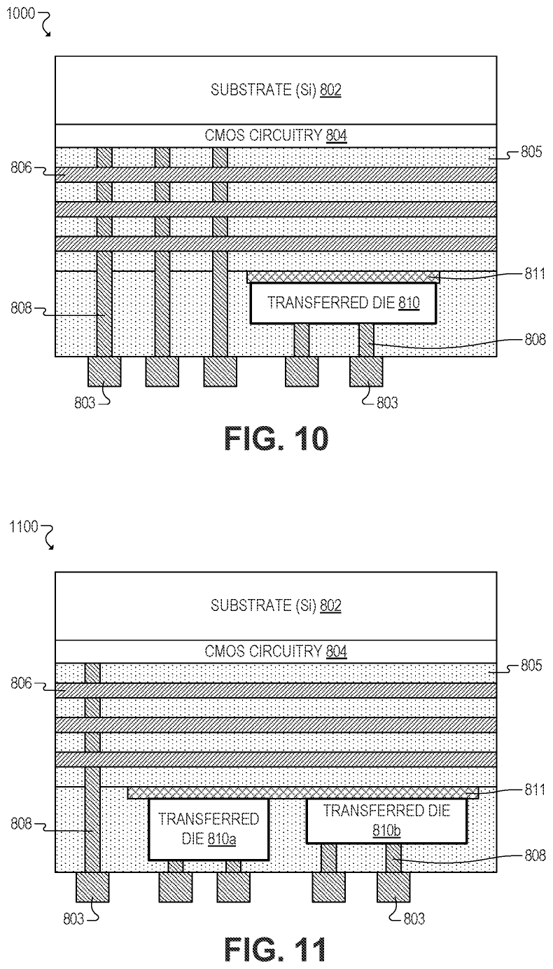

FIG. 10 illustrates another example embodiment of an integrated circuit (IC) 1000 with a selectively transferred IC die 810 integrated with CMOS circuitry 804. In the illustrated embodiment, IC 1000 is similar to IC 900, but the transferred die 810 is selectively transferred onto a raised mesa 811 after all routing layers 806 are finished, and bumps 803 are formed on the bottom for external connectivity.

FIG. 11 illustrates an example embodiment of an integrated circuit (IC) 1100 with multiple IC dies 810a-b integrated with CMOS circuitry 804 using selective transfer technology. In the illustrated embodiment, IC 1100 is similar to IC 1000, but two dielets 810a-b with different dimensions (e.g., thickness, area) are integrated with the CMOS circuitry 804 via selective transfers. For example, the two dielets 810a-b may have different areas and thicknesses, may include a combination of passive and active devices, and/or may originate from two different processes (e.g., Group III-V (e.g., GaN) and silicon (Si) fabrication processes, respectively). Via orientation in each dielet 810a-b may vary depending on the selective transfer/bonding strategy (e.g., single transfer vs. multiple transfers). In the illustrated embodiment, the dies 810a-b are selectively transferred after the metal stack 806 is fabricated. In other embodiments, however, additional metal 806 and dielectric layers 805 may be formed on top/over the transferred dies 810a-b (i.e., below the transferred dies 810a-b in the orientation shown), similar to IC 900.

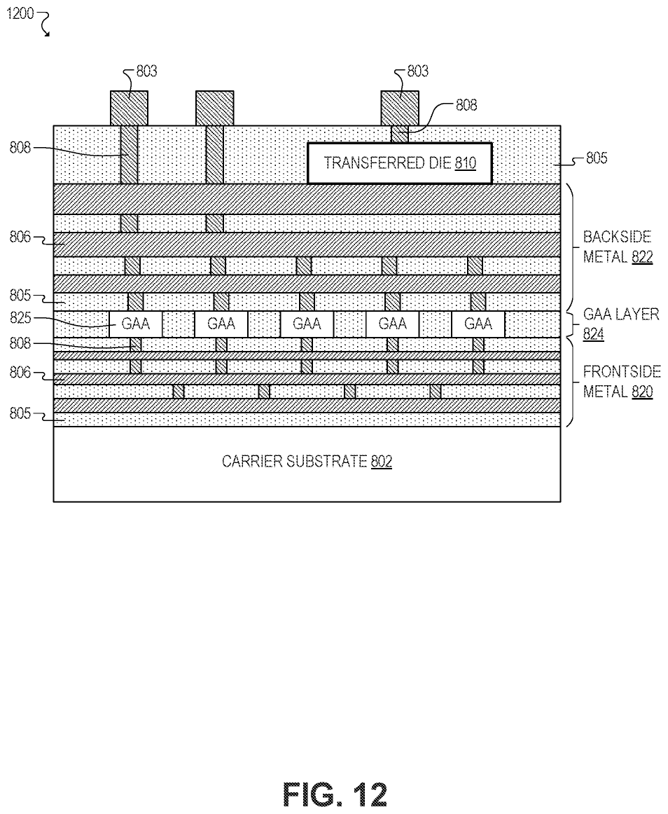

FIG. 12 illustrates an example embodiment of an integrated circuit (IC) 1200 with an IC die 810 integrated with gate-all-around (GAA) transistors 825 using selective transfer technology. For GAA technologies, it may be easier and more cost effective to integrate the transferred die 810 via selective transfer to the backside metallization (BSM) stack 822 due to the metal pitch and alignment requirements compared to the frontside metallization (FSM) stack 820, as the metal layers 806 in the BSM stack 822 typically have a larger pitch and greater thickness than the metal layers 806 in the FSM stack 820 (e.g., in some cases, the BSM 822 pitches may be in the range of 180 nm to 4 μm depending on the metal layer 806). In some embodiments, however, the transferred die 810 may be selectively transferred to the FSM stack 820, or multiple dies may be selectively transferred to both the BSM 822 and FSM 820 stacks. In the illustrated embodiment, a GAA transistor layer 824 with GAA transistors devices 825 is fabricated using an advanced process, and after the FSM 820 and BSM 822 stacks are formed, a die 810 (e.g., with high-voltage circuitry) fabricated using another process is selectively transferred to the BSM stack 822. Moreover, IC 1200 is attached to a carrier substrate 802 for structural/mechanical support.

FIGS. 13A-B illustrate an example embodiment of a radio frequency (RF) transceiver system 1300 to transmit, receive, and/or process RF signals. In particular, a cross-section view of the RF transceiver 1300 is shown in FIG. 13A and a block diagram of the RF transceiver 1300 is shown in FIG. 13B. In the illustrated embodiment, the RF transceiver 1300 includes digital circuitry 1304 (e.g., a CMOS chip with CMOS circuitry) fabricated on a silicon substrate 1302, along with multiple dies/dielets/chiplets 1310-1360 with various active and passive devices, which are integrated with the digital circuitry 1304 via selective transfer. In other embodiments, however, certain chiplets may be integrated using other techniques, such as pick and place assembly. The RF transceiver 1300 also includes ILD layers 1305 patterned with interconnects 1306 (e.g., traces, vias, pads) to connect the digital circuitry 1304 and the respective chiplets 1310-1360 and provide off-chip connectivity to other components (e.g., for power and I/O from the IC package (not shown)).

The selectively transferred chiplets include a high-voltage electrostatic discharge (ESD) protection chiplet 1310, an input/output (I/O) subsystem chiplet 1320 with thick gate oxide transistors (TG I/O), an analog transceiver subsystem chiplet 1330 (e.g., to send/receive analog signals and/or perform analog signal processing), a Group III-V amplifier chiplet 1340 (e.g., a power amplifier (PA) and low noise amplifier (LNA) with Group III-V transistors), a surface acoustic wave (SAW)/bulk acoustic wave (BAW) chiplet 1350 (e.g., containing SAW/BAW devices and filters), and an antenna chiplet 1360 (e.g., containing one or more antennas).

In the illustrated embodiment, the PA/LNA chiplet 1340 and the SAW/BAW chiplet 1350 are selectively transferred onto mesas 1308, while no mesas are present for the other chiplets (e.g., 1310, 1320, 1330, 1360), which is indicative of the particular selective transfer process used to transfer each chiplet (e.g., a single selective transfer directly from a donor substrate as described with respect to FIGS. 1A-I, or multiple selective transfers using intermediate donor/stamp substrates as described with respect to FIGS. 4A-C). In other embodiments, however, any selective transfer process may be used to transfer the respective chiplets.

As shown in FIG. 13B, the digital chip 1304 includes digital (e.g., CMOS) circuitry. The analog transceiver chiplet 1330 includes an analog-to-digital converter (ADC), a digital-to-analog converter (DAC), intermediate-frequency (IF) amplifiers, bandpass filters (BPFs), mixers, and frequency synthesizers. The Group III-V amplifier chiplet 1340 includes a power amplifier (PA) and a low noise amplifier (LNA). The SAW/BAW chiplet 1350 includes SAW/BAW bandpass filters (BPFs) or acoustic wave filters. The antenna chiplet 1360 includes one or more antennas to transmit and/or receive RF signals. The ESD chiplet 1310 may include one or more ESD protection devices, such as a diode that provides a leakage path for components that may come in contact with, or close proximity to, an electrically-charged object (e.g., the human body, manufacturing equipment/tools), thus protecting the circuitry by absorbing/suppressing static charges or short-pulse voltages.

Moreover, the digital chip 1304 and respective chiplets 1310-1360 may be fabricated using different technology-specific optimized processes. For example, the digital chip 1304, ESD chiplet 1310, TG I/O chiplet 1320, and analog transceiver chiplet 1330 may be fabricated using different CMOS processes; the Group III-V amplifier chiplet 1340 may be fabricated using a process optimized for Group III-V (e.g., GaN) semiconductors; and the SAW/BAW chiplet 1350 and the antenna chiplet 1360 may be fabricated using other technology-specific optimized processes.

In this manner, the digital circuitry 1304 can be fabricated using advanced process optimized for CMOS/digital technology, and the respective chiplets 1310-1360 can be fabricated using other technology-specific processes and then integrated with the digital CMOS chip 1304 via selective transfer (e.g., as part of the CMOS/digital process used to fabricate the digital circuitry 1304), thus integrating the various components into a single monolithic chip while also fabricating them separately using optimal process technologies.

### Fine-Grain Integration of Group III-V Devices

As used throughout this disclosure, a Group III-V material refers to any material containing elements from groups III and V of the periodic table (e.g., gallium nitride (GaN), aluminum gallium nitride (AlGaN), gallium arsenide (GaAs), indium gallium arsenide (InGaAs), indium phosphide (InP), indium gallium nitride (InGaN), aluminum indium arsenide (AlInAs), aluminum indium gallium nitride (AlInGaN), aluminum gallium indium phosphide (AlGaInP), aluminum indium gallium arsenide (AlInGaAs)), and a Group IV material refers to any material containing at least one element from group IV of the periodic table (e.g., silicon (Si)). Similarly, a Group III-V device may refer to any device that includes at least one Group III-V material, and a Group IV device may refer to any device that includes at least one Group IV material.

While silicon (Group IV) is ubiquitous in logic and digital applications, Group III-V materials are proven high-mobility channels and are well-suited for applications such as RF, power, and photonics. Thus, in some cases, it may be beneficial to integrate Group IV materials with Group III-V materials to take advantage of their respective benefits. It is extremely challenging to integrate Group III-V semiconductor materials (e.g., GaN, AlGaN, GaAs, InGaAs, InP) with Group IV semiconductor materials (e.g., Si), however, due to inherent crystals mismatch, incompatible processes, and lack of p-channel performance in III-V materials.

While Group III-V and Group IV materials can be integrated using full layer transfers (e.g., transferring a full Group III-V layer over a Group IV layer/substrate), unneeded areas of the transferred layer must be etched off after the transfer, which increases costs and process complexity, and applications of this approach are typically limited to GaN/PMOS chiplets and older process nodes.

Moreover, while chiplets from different process technologies/materials (e.g., Group IV and Group III-V) can be integrated using pick-and-place assembly, that approach has various downsides, including package parasitics incurred from routing signals off die, complex co-design of integrated circuits (IC) and the IC package which requires integration of multiple design kits and tools, and limitations on chiplet integration due to package design rules and other constraints (e.g., constraints on chiplet size/downscaling).

Accordingly, this disclosure presents methods for fine-grain integration of Group III-V and Group IV materials using selective transfer technology, along with devices and systems formed using the same. In some embodiments, for example, Group III-V devices and integrated circuits may be fabricated separately in an optimized process and then selectively transferred onto a silicon CMOS substrate/wafer during a CMOS fabrication process. As an example, an XPU (e.g., CPU, GPU, ASIC, FPGA) could be fabricated on silicon using a CMOS process, and then a voltage regular fabricated using a Group III-V (e.g., GaN) process could be selectively transferred over the CPU (e.g., to regulate voltage supplied to the CPU). In this manner, the described solution solves the problem of integrating Group III-V and Group IV semiconductor materials monolithically to achieve the best system performance.

The described solution provides various advantages, including enabling low parasitics between Group III-V devices and silicon CMOS devices, sharing the same far backend interconnects for Group III-V devices and silicon CMOS devices, eliminating the need for complex integration of multiple design kits and tools, and eliminating limitations from package design rules. Further, selectively transferring III-V devices can enable selective integration with later node devices and may enable connectivity at upper metal layers to further improve flexibility. For example, III-V circuits can be fabricated and then interconnects can be fabricated on top (e.g., for flip chip). The described solution can also achieve high current density (e.g., up to ˜30 amps (A)/mm²). Moreover, this solution has a variety of applications, including power management, power gates, voltage regulators, voltage converters (e.g., switched capacitors with monolithic metal-insulator-metal (MIM) stacks), and radio frequency (RF) subsystems, among others.

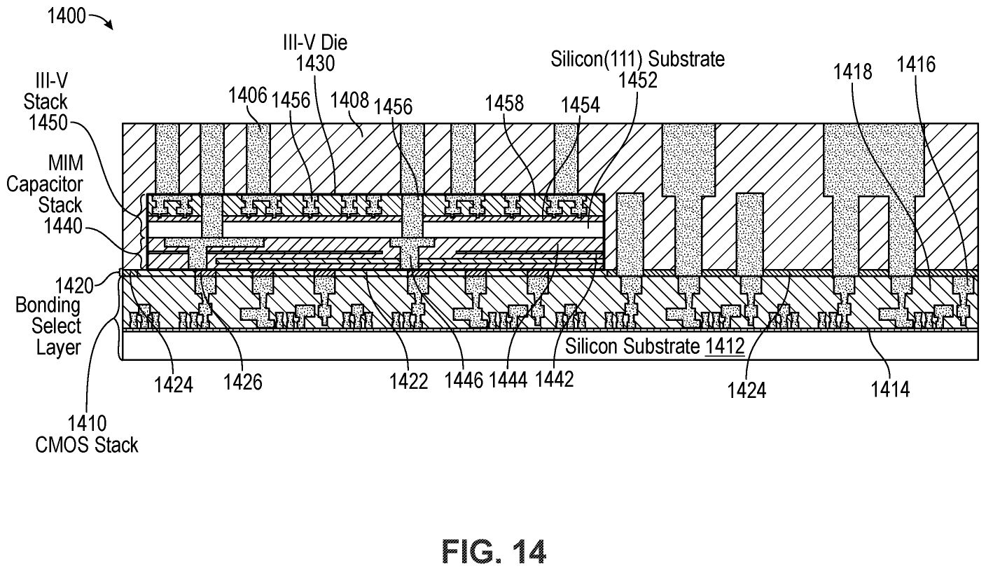

FIG. 14 illustrates an example of an integrated circuit (IC) 1400 with a Group III-V die 1430 integrated with silicon CMOS circuitry 1410 using selective transfer technology. For example, the III-V die 1430 may contain III-V (e.g., GaN) transistor devices, while the CMOS circuitry 1410 may contain CMOS transistor devices. Moreover, the III-V die 1430 may be fabricated in a separate process and then transferred/integrated over the silicon CMOS substrate 1412 using selective transfer technology.

In the illustrated embodiment, IC 1400 includes a CMOS stack 1410, a bonding select layer 1420, a transferred III-V die 1430, an interconnect 1406, and an inter-layer dielectric (ILD) 1408 to fill the remaining areas.

The CMOS circuitry/stack 1410 includes a silicon substrate 1412, a layer of CMOS devices 1414 (e.g., CMOS transistors) over the silicon substrate 1412, an interconnect layer 1416 over the CMOS device layer 1414, and ILD 1418 to fill the remaining areas. In some embodiments, for example the CMOS circuitry 1410 may contain digital circuitry/logic, such as processing circuitry associated with a processor (e.g., XPU, CPU, GPU, ASIC, FPGA), memory circuitry, etc.

The bonding select layer 1420 is formed over the CMOS stack 1410 and is patterned with one or more adhesive 1422 and non-adhesive 1424 areas/materials. For purposes of this disclosure, adhesive areas 1422 may refer to areas with relatively high adhesiveness and non-adhesive areas 1424 may refer to areas with relatively low or no adhesiveness. The adhesive area 1422 is also patterned with hybrid bond interconnect (HBI) pads 1426. Moreover, in the illustrated embodiment, the adhesive area 1422 corresponds to the position of the III-V die 1430, which is selectively transferred to the adhesive area 1422 and electrically connected to the CMOS stack 1410 via the HBI pads 1426.

The selectively-transferred III-V die 1430 includes a III-V device stack 1450 along with an optional integrated metal-insulator-metal (MIM) capacitor stack 1440.

The III-V device stack 1450 includes a silicon (111) substrate 1452, a layer of III-V front-end devices 1454 (e.g., III-V/GaN transistors), an interconnect layer 1456 (including through-silicon vias (TSVs)), and an ILD 1458 to fill the remaining areas.

The integrated MIM capacitor stack 1440 includes a stack of alternating metal 1442 and insulator 1444 layers, along with an interconnect 1446.

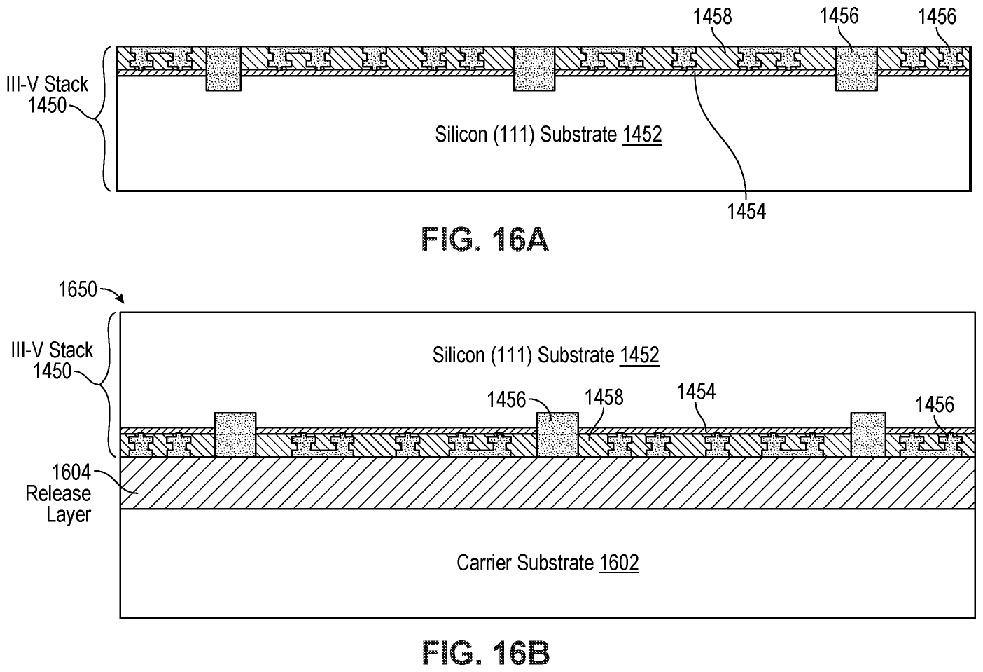

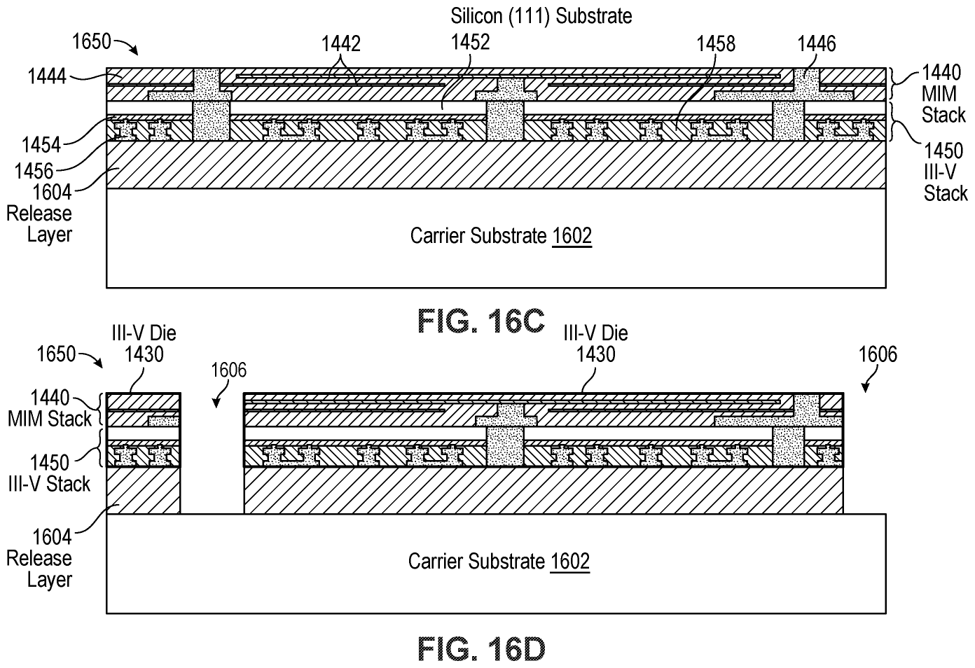

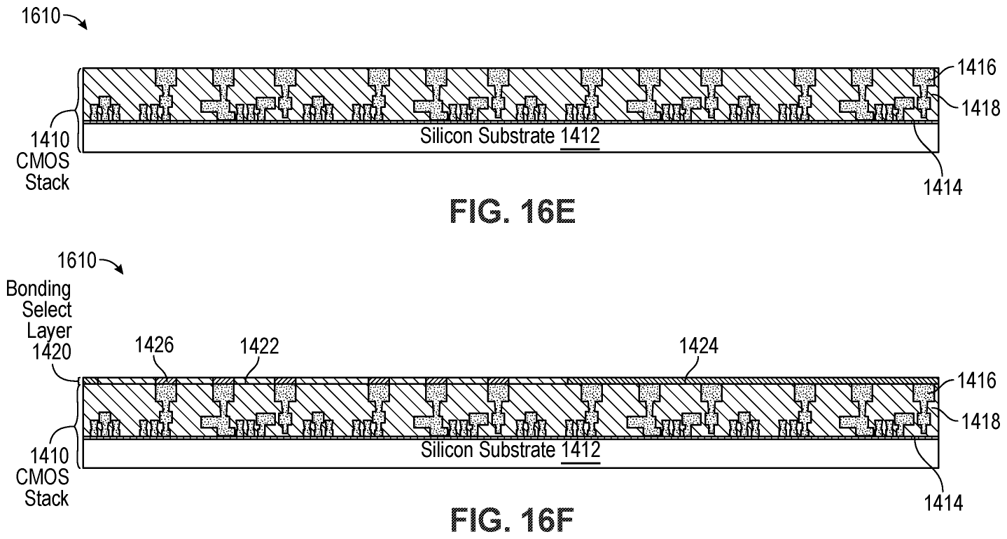

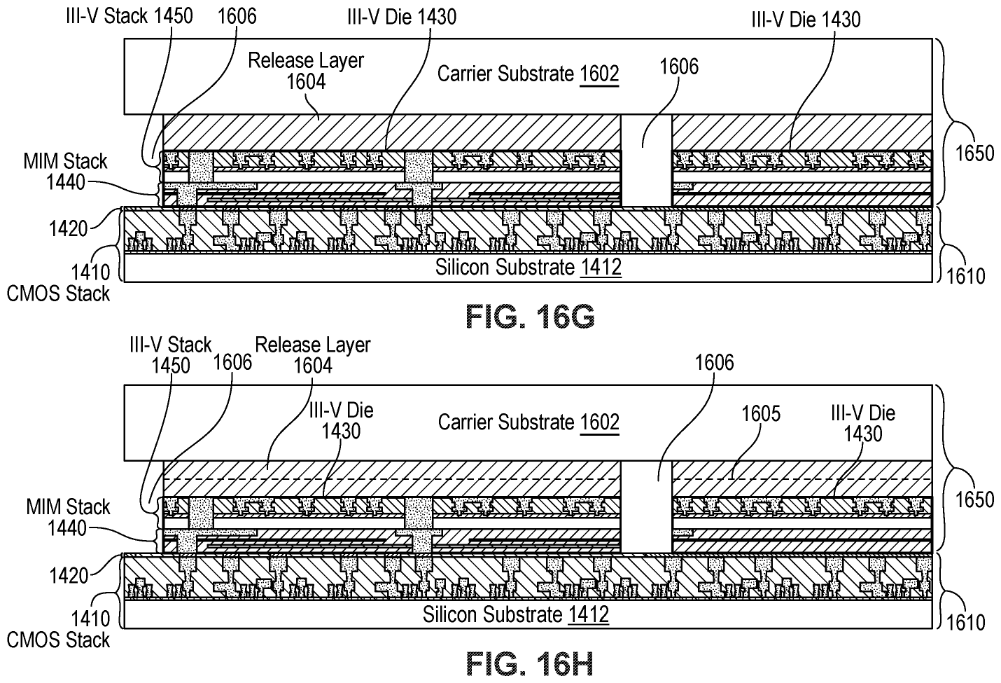

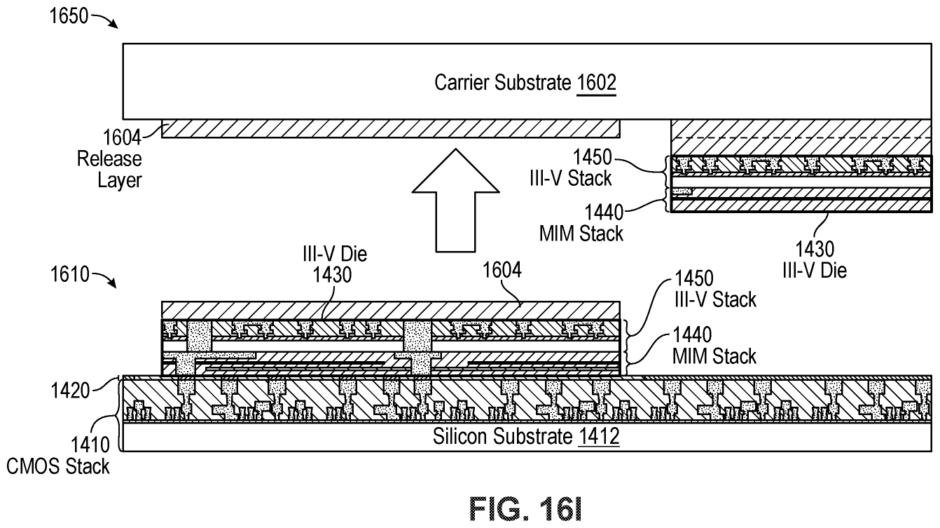

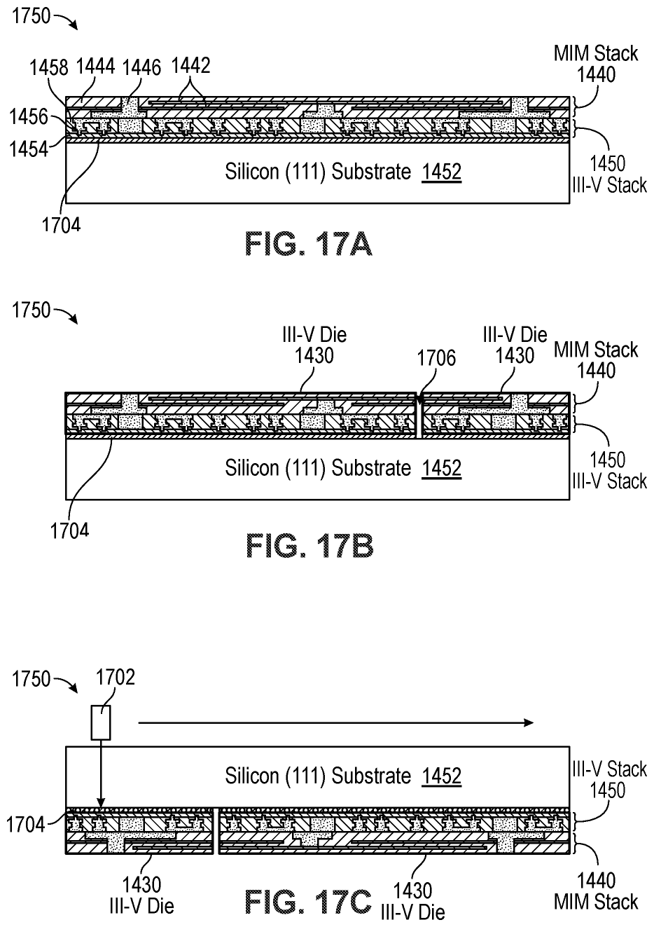

In some embodiments, the process flow for fabricating IC 1400 may include fabricating the III-V die 1430 in a III-V optimized process, fabricating the CMOS stack 1410 in a CMOS process, forming the bonding select layer 1420 over the CMOS stack 1410, selectively transferring the III-V die 1430 to the CMOS stack 1410, and then forming the remaining interconnect 1406 and ILD 1408 layers. The process flow is described in further detail with respect to FIGS. 16A-I.

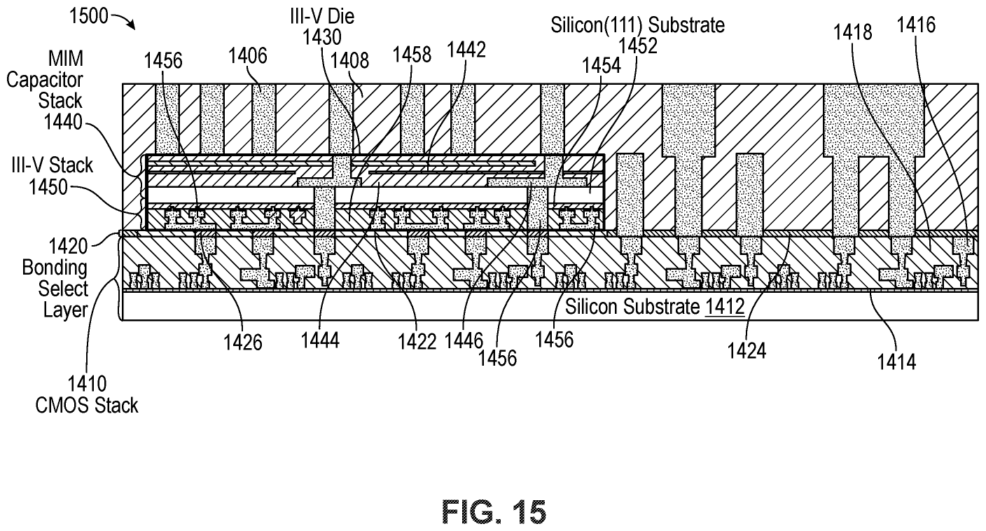

FIG. 15 illustrates another example of an integrated circuit (IC) 1500 with a Group III-V die 1430 integrated with silicon CMOS circuitry 1410 using selective transfer technology. Compared to the embodiment in FIG. 14, the III-V stack 1450 is flipped upside down and moved below the MIM capacitor stack 1440, thus enabling a closer proximity between the silicon CMOS devices 1414 and the III-V devices 1454 to achieve even lower parasitics.

FIGS. 16A-I illustrate an example process flow for integrating Group III-V devices with CMOS devices using selective transfer technology. In some embodiments, for example, the illustrated process flow may be used to fabricate the ICs 1400, 1500 of FIGS. 14 and 15.

In FIG. 16A, III-V (e.g., GaN) devices 1454 and interconnects 1456 are fabricated on a silicon (111) substrate 1452 (e.g., Si (111) wafer or panel) with added dielectric 1458 on top to facilitate bonding. In some embodiments, the dielectric may be SiO₂, SiN, SiCN, etc. The resulting stack of layers is collectively referred to as the III-V stack 1450.

In FIG. 16B, the III-V stack 1450 is bonded to a carrier substrate 1602 (e.g., Si) that includes a release layer 1604. The release layer 1604, which may also be referred to as the bond/debond layer or debond absorption layer, may include any of the materials, layers, and/or structures described throughout this disclosure with respect to the release layer (e.g., in connection with FIGS. 1-7), such as one or more metal and/or dielectric layers (e.g., blanket or patterned). As described further below (e.g., with respect to FIG. 16H), the release layer 1604 may be subsequently weakened using a process such as laser-induced heating to enable subsequent debonding to occur.

In FIG. 16C, the silicon (111) substrate 1452 is thinned to reveal the through-silicon via (TSV) interconnect structures 1456, which are used to provide electrical connections through the III-V stack 1450. After thinning the substrate 1452, integrated capacitors 1440—such as high-density MIM capacitors—are (optionally) fabricated over the III-V stack 1450. The capacitor stack 1440 includes a stack of metal layers 1442 separated by insulator layers 1444 (e.g., metal 1442, insulator 1444, metal 1442) along with an interconnect 1446.

In the illustrated embodiment, the III-V stack 1450 and MIM capacitor stack 1440 are arranged according to the embodiment shown in FIG. 14. In other embodiments, however, the III-V stack 1450 and MIM capacitor stack 1440 may be arranged according to the embodiment shown in FIG. 15.

In FIG. 16D, isolation lanes 1606 are etched through the capacitor and III-V stacks 1440, 1450 down through (or down to) the release layer 1604, thus forming partially singulated dies 1430 that include the III-V and capacitor stacks 1450, 1440. The resulting substrate stack is collectively referred to as the III-V donor substrate 1650.

In FIG. 16E, a silicon CMOS substrate 1610 is fabricated (e.g., using a leading advanced node CMOS process), such as a CMOS wafer or panel. The CMOS substrate 1610 includes a base silicon substrate 1412, a layer of CMOS devices 1414, an interconnect layer 1416, and an ILD 1418 (collectively referred to as the CMOS stack 1410).

In FIG. 16F, a bonding select layer 1420 is formed over the CMOS stack 1410 on the CMOS substrate 1610. The bonding select layer 1420 is patterned with adhesive areas 1422 and non-adhesive areas 1424, which define the respective areas on the CMOS substrate 1610 where the III-V dies 1430 from FIG. 16D will and will not be selectively transferred.

In some embodiments, the adhesive areas 1422 may include materials such as silicon dioxide (SiO₂) or silicon carbon nitride (SiCN) to promote strong oxide fusion bonds, or silicon carbide (SiC) to provide lower thermal contact resistance compared to SiO₂ or SiCN. Further, in some embodiments, the non-adhesive areas 1424 may include materials such as silicon nitride (Si₃N₄) to form weak or no bonds.

In various embodiments, however, any suitable surface treatments or other techniques may be used to control the level of adhesion on different areas of the CMOS substrate 1610 (e.g., to form adhesive and non-adhesive areas 1422, 1424 for selective transfers), including, without limitation, surface topography variations (e.g., mesas/protrusions, recesses), use of materials with high and/or low adhesion, treatments using hydrophobic materials and/or self-assembled monolayers (SAMs), and/or surface activation techniques, as described throughout this disclosure. Further, many methods exist in order to promote weak bonding or no bonding where desired, including, without limitation, surface preparation techniques (e.g., surface modification to change surface energy) and introduction of topographical contrasts or step heights (so that bonding occurs in elevated regions which make contact and not in the depressed regions).

In the illustrated embodiment, the adhesive areas 1422 in the bond select layer 1420 are also patterned with intraconnect structures 1426, such as copper hybrid bond interconnect (HBI) pads, to enable direct dielectric-to-dielectric and metal-to-metal bonding (e.g., hybrid bonding) in subsequent steps (e.g., to form electrical connections with the bonded components). Thus, since the bonding select layer 1420 may require HBI copper patterning, it may be advantageous to form the bonding layer 1420 with a single film (e.g., adhesive) material across the entire CMOS substrate 1610, complete fabrication up to the HBI chemical mechanical polish (CMP) step, and then selectively expose the CMOS substrate 1610 to fluorocarbon-based chemistry to leave a monolayer of fluorine-terminated film on the areas 1424 where no or weak adhesion is desired.

In FIG. 16G, the III-V donor substrate 1650 and the silicon CMOS substrate 1610 from FIGS. 16D and 16F are selectively bonded together. For example, due to the bonding select layer 1420 on the CMOS receiver substrate 1610, strong hybrid bonding occurs in the adhesive areas 1422 where III-V dies 1430 are meant to be selectively transferred from the III-V donor substrate 1650, and weak or no bonds occur in the non-adhesive areas 1424 where no III-V dies are meant to be transferred. Moreover, the intraconnects 1426 in the bonding select layer 1420 enable direct metal-to-metal bonding to provide electrical connections directly between the respective interconnect fabrics of the silicon CMOS devices 1414 and the III-V devices 1454.

In FIG. 16H, the release layer 1604 on the III-V donor substrate 1610 is weakened 1605 (e.g., using selective or blanket laser exposure/heating) to enable subsequent debonding to occur.

In FIG. 16I, the III-V donor substrate 1650 is mechanically separated and debonded from the CMOS substrate 1610 (e.g., using a mechanical cleave), which causes the III-V dies 1430 bonded to adhesive areas 1422 on the CMOS substrate 1610 to debond from the III-V donor substrate 1650 and remain bonded to the CMOS substrate 1610 (e.g., due to the strong hybrid bonds formed by the adhesive areas 1422 on the CMOS substrate 1610 versus the weakened release layer 1604 on the III-V donor substrate 1650).

The remaining III-V dies 1430 on non-adhesive areas 1424 of the CMOS substrate 1610 remain attached to the III-V donor substrate 1650 since no bond, or only a very weak bond, was formed with the CMOS substrate 1610.

In some embodiments, the portion of the release layer 1604 remaining on the III-V die 1430 after the transfer can either be patterned with vias (not shown) to contact subsequent metal layers 1406 formed over the III-V die 1430 or it can be removed completely if the parasitics are sensitive to the dielectric properties used in the release layer 1604 for laser/IR debonding (e.g., depending on the design/materials of the debond stack used in the release layer 1604).

In some cases, however, it may be challenging to remove the residual IR debond films in the release layer 1604 from transferred dies/chiplets 1430, as common techniques such as chemical mechanical polishing (CMP) and etching may have potential issues either due to topography or etch selectivity of different film materials. Thus, in some cases, it may be preferable to leave some of the residual IR debond films 1604 on the transferred dies/chiplets 1430 if they do not create undesired electrical problems.

Transfer of the dies/chiplets 1430 is possible without transferring any of the metals that may be used in the release layer 1604 (e.g., since the metals may be ablated during laser debonding), thus leaving only dielectric materials in the release layer 1604 (e.g., silicon dioxide (SiO₂), silicon nitride (Si₃N₄), silicon oxynitride (SiON), silicon carbide (SiC), silicon carbon nitride (SiCN), silicon oxycarbon nitride (SiOCN), aluminum oxide (Al₂O₃), low-k dielectrics such as carbon-doped oxide (CDO) or porous silicon dioxide (SiO₂), titanium dioxide (TiO₂), tantalum oxide (Ta₂O₅))) after the transfer. If the release layer 1604 is completely removed, other artifacts from the selective transfer process may still remain, such as the bond energy pattern of the various adhesive and non-adhesive areas 1422, 1424 in the bond select layer 1420 or any other surface treatments that are used to control the level of adhesion on the CMOS substrate 1610 (e.g., raised mesas). Moreover, the transferred III-V die 1430, which is typically very thin and may have a high aspect ratio, is also indicative of the selective transfer process, as a thin and/or high-aspect-ratio die cannot be attached using pick-and-place assembly.

The remaining steps (not shown) to complete the embodiments shown in FIGS. 14 and 15 include ILD 1408 (e.g., SiO₂) fill and metal (e.g., copper) damascene steps complete the metal interconnects 1406.

FIGS. 17A-E illustrate another example process flow for integrating Group III-V devices with CMOS devices using selective transfer technology. In the illustrated example, the III-V devices (e.g., GaN transistors) are integrated via selective transfer directly from the III-V fabrication wafer. Thus, no transfer to a carrier wafer is required, and the III-V fabrication wafer can be reused for multiple transfers of III-V devices.

In FIG. 17A, a III-V stack 1450 (e.g., with GaN transistor devices 1454) and a metal-insulator-metal (MIM) capacitor stack 1440 are fabricated on a lattice-matched release layer 1704 formed over a silicon (111) wafer 1452. In some embodiments, the release layer 1704 may include lattice-matched epitaxial thin film(s) suitable for infrared (IR) laser debonding, such as epitaxial niobium nitride (NbN), or an NbN/silicon carbide (SiC)/NbN stack, with good lattice match to III-V materials such as GaN.

In FIG. 17B, isolation lanes 1706 are etched through the capacitor and III-V stacks 1440, 1450 down to/through the release layer 1704, thus forming partially singulated dies/chiplets 1430 that include the III-V and capacitor stacks 1450, 1440. The resulting wafer with III-V dies 1430 is collectively referred to as the III-V donor wafer 1750.

In FIG. 17C, the release layer 1704 of the III-V donor wafer 1750 is blanket exposed to a laser 1702 to weaken the release layer 1704 while still providing residual adhesion to the III-V dies 1430. In other embodiments, however, the release layer 1704 may be selectively exposed to the laser 1702 in the areas below the target dies 1430 to weaken those areas of the release layer 1704 immediately before each transfer.

In FIG. 17D, the III-V donor wafer 1750 is selectively bonded to a CMOS wafer 1710 patterned with raised dielectric mesas 1720 and hybrid-bonded interconnect (HBI) pads 1722 on the surface (referred to as HBI mesas). In particular, the raised mesas 1720 and HBI pads 1722 on the CMOS wafer 1710 are bonded to certain dies/chiplets 1430 in corresponding locations on the III-V donor wafer 1750, while the remaining dies 1430 on the III-V donor wafer 1750 remain unbonded to the CMOS wafer 1710 (e.g., due to the lack of raised mesas 1720 and pads 1722 in certain areas of the CMOS wafer 1710).

In FIG. 17E, the III-V donor wafer 1750 is mechanically separated and debonded from the CMOS wafer 1710, which causes the III-V dies 1430 bonded to the mesas 1720 on the CMOS wafer 1710 to debond from the III-V donor wafer 1750 and remain bonded to the CMOS wafer 1710 (e.g., due to the strong bond provided by the mesas 1720 versus the weakened release layer 1704 on the III-V donor wafer 1750). The remaining III-V dies 1430 remain attached to the III-V donor wafer 1750 since those dies 1430 were not bonded to the CMOS wafer 1710 (e.g., due to the absence of mesas 1720 and pads 1722 in certain areas of the CMOS wafer 1710).

Any residue or layers such as the bonding dielectric from the release layer 1704 that remains on the transferred dies 1430 may be removed, and the remaining interconnects 1406 and ILD layers 1408 may be formed (not shown). The III-V donor wafer 1750 can then be reused to transfer the remaining dies 1430 to another CMOS wafer (not shown).

### Fine-Grain Integration of RF Antennas, Interconnects, and Passives

Radio frequency (RF) antennas, interconnects (e.g., transmission lines), and passives (e.g., inductors) typically have material and substrate thickness requirements that are incompatible or opposite of those imposed by advanced semiconductor technologies such as CMOS (e.g., smaller pitches, thicker dielectric and metal layers, filling design rules with high metal density, etc.). However, high-frequency circuitry for communication (e.g., I/O and serializers/deserializers (SerDes), Wi-Fi, 5G/6G wireless, millimeter Wave (mmWave) to sub-terahertz (sub-THz) waveguide-based I/O) and sensing needs to be tightly integrated with advanced digital processors in order to achieve higher power, performance, area, and cost (PPAC) metrics.

In some cases, RF-optimized stacks may be monolithically integrated using an advanced semiconductor process. However, integration of multiple thick metal and dielectric layers is limited by wafer bow (among other design considerations) and complicates process integration. Moreover, monolithic integration does not allow fine-grain optimization and fabrication of the diverse structures/devices required (e.g., RF inductors drive different requirements than RF transmission lines or antennas). Monolithic integration of such RF-optimized layers also requires those layers, by definition, to be present across the entire wafer/die even though RF circuitry may only occupy a small fraction of the die area (e.g., for a 4-channel RF transceiver chip or a power amplifier (PA), passives may only occupy roughly 20% of the die). Further, monolithic fabrication requires copper fill or thieving (e.g., an array of copper rectangles) to be applied across the chip in areas with no metal to make the density of metal across the chip as uniform as possible, which increases costs and manufacturing time and may degrade performance.

Alternatively, in some cases, 2.5D and 3D integration technologies may be used to enable co-integration of chiplets (e.g., side by side and/or stacked) from several substrate technologies, such as silicon (Si), Group III-V materials (e.g., GaN), or glass. While these technologies allow optimal substrates and processes to be mixed and matched for different subsystems, they do not support fine-grain disaggregation and integration down to the device/intellectual property (IP) level. In particular, standard integration processes (e.g., pick-and-place) typically require chiplets to have a minimum area of several square millimeters (mm²), which is insufficient for device-level fine-grain disaggregation/integration of chiplets with dimensions on micrometer-level scale (e.g., below 1 mm², such as 10×10 μm, 100×100 μm, 900×900 μm, etc.). For example, an on-chip inductor may have an area of roughly 175×175 μm, and matching networks on a power amplifier may have an area of roughly 50×50 μm, both of which are way too small to be individually fabricated and assembled using standard pick-and-place assembly.

Accordingly, this disclosure presents methods for fine-grain integration of RF antennas, interconnects, and other passives (e.g., inductors) using selective transfer technology, along with devices and systems formed using the same. For example, selective transfer technology may be utilized to enable fine-grain integration of such components on top of a semiconductor substrate (e.g., wafer or die) fabricated using an advanced CMOS process. Accordingly, this solution enables architectures with integrated RF and digital components with support for optimized selections of semiconductor processes down to the device/IP level.

The described solution provides various advantages. For example, RF passives can be fabricated in separate processes from CMOS circuitry and then selectively transferred to the same substrate, and as a result, they do not need to be compatible with CMOS fabrication requirements (e.g., temperature, materials, tools, etc.). Moreover, RF passives can be integrated only where needed rather than across the entire substrate, which is crucial for semiconductor scaling, as RF passives typically have dimensions ranging from 50×50 μm to 500×500 μm, which means they cannot be integrated in a cost-efficient manner using traditional 2.5D/3D integration processes (e.g., chiplet pick-and-place assembly). Further, fabricating components on another wafer and then integrating them with a CMOS chip via selective transfer significantly reduces the amount of copper fill or thieving required to achieve uniform metal density, which reduces costs and manufacturing time and improves performance.

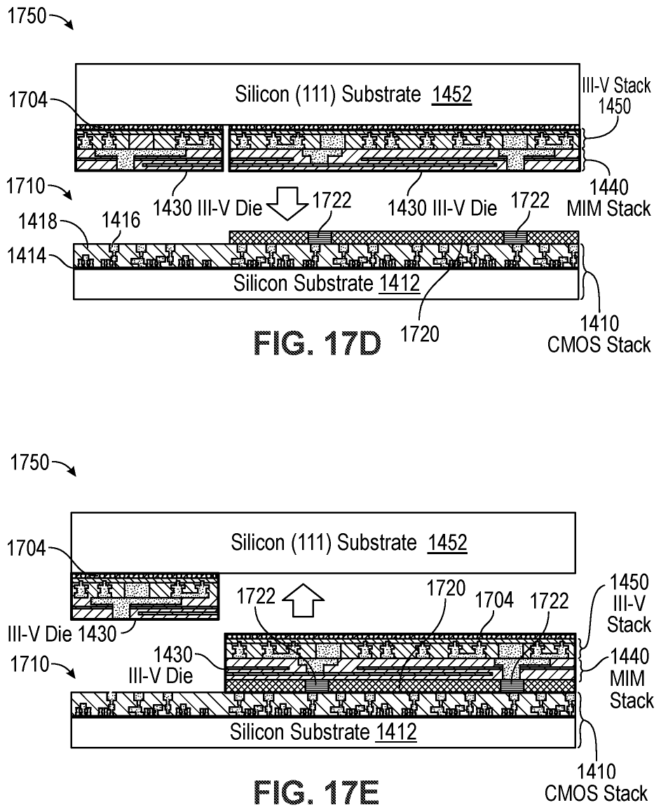

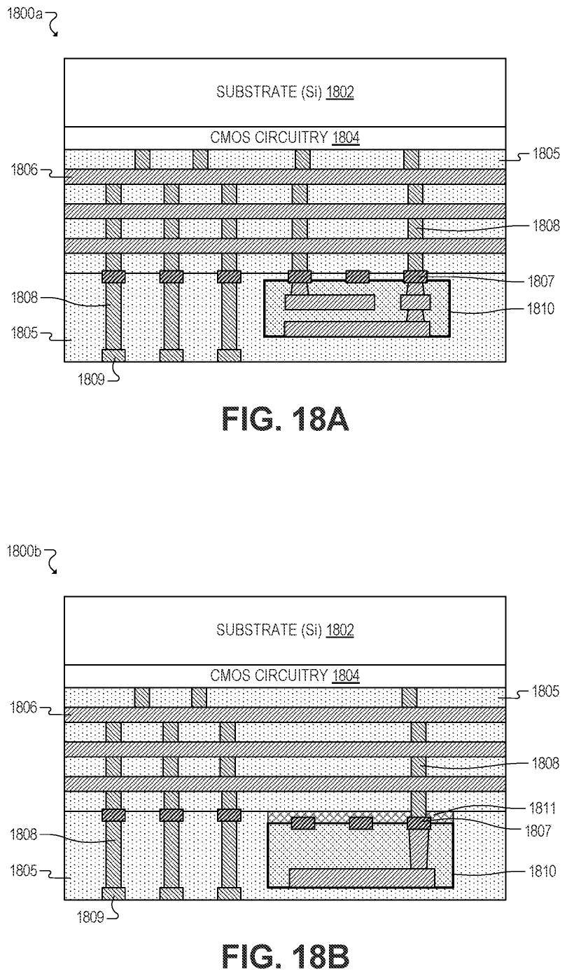

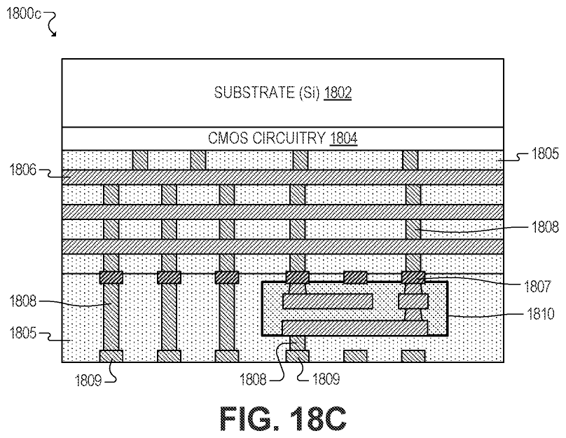

FIGS. 18A-C illustrate various examples 1800a-c of a passive RF dielet integrated with CMOS circuitry using hybrid bonded interconnect (HBI) connectivity. In the illustrated examples, CMOS circuitry 1804 (e.g., CMOS logic/devices/transistors) is fabricated on a silicon substrate 1802 (e.g., using an advanced CMOS process), along with multiple inter-layer dielectric (ILD) layers 1805, routing layers 1806 (e.g., interconnect/conductive traces), vias 1808, and HBI pads 1807. Further, a dielet 1810 with passive RF circuitry is fabricated separately (e.g., using another technology-specific process) and then integrated with the CMOS circuitry 1804 via selective transfer (e.g., as described with respect to FIGS. 1-7 above and throughout this disclosure). For example, the dielet 1810 is selectively transferred from a donor substrate and hybrid bonded to the HBI pads 1807 below the routing layers 1806, thus interconnecting the passive RF dielet 1810 with the CMOS circuitry 1804 via a hybrid-bonded interconnect. Further, through-dielectric vias (TDVs) 1808 are formed around the transferred dielet 1810 and electrically coupled to conductive pads 1809 on the bottom for external connectivity (e.g., connectivity to the IC package or other components (not shown)). As shown, the completed ICs 1800a-c are flipped relative to the orientation in which they were fabricated (e.g., for flip chip packaging).

The dielet 1810 may include any type of passive RF circuitry. In some embodiments, for example, the dielet 1810 may include a multiturn inductor or transformer, which are devices that are used in matching networks across several transceiver sub-circuits (e.g., connecting to C4 bumps, interstage matching networks of power amplifier (PA)/low noise amplifier (LNA) circuits, matching networks between subsystems such as mixer to amplifier, amplifier to antenna etc.). Alternatively, or additionally, the dielet 1810 may include passive RF devices such as combiners, splitters, circulators, etc.

In FIG. 18A, a dielet 1810 containing a transformer is selectively transferred using the process flow of FIGS. 4A-C (e.g., multiple transfers using an intermediate donor/stamp substrate), and thus no mesa is present.

In FIG. 18B, a dielet 1810 containing an inductor is selectively transferred using the process flow of FIGS. 1A-I (e.g., a single selective transfer directly from a donor substrate), and thus a mesa 1811 is present (e.g., a raised structure with dielectric materials and metal for hybrid bonding).

In FIG. 18C, an interconnect to the other side of a transformer dielet 1810 is enabled by a TDV 1808 and a pad 1809 on the bottom. This design is particularly useful for applications where the RF signal needs to be driven off-die (e.g., connecting to an antenna, another subsystem, and/or the IC package (not shown)).

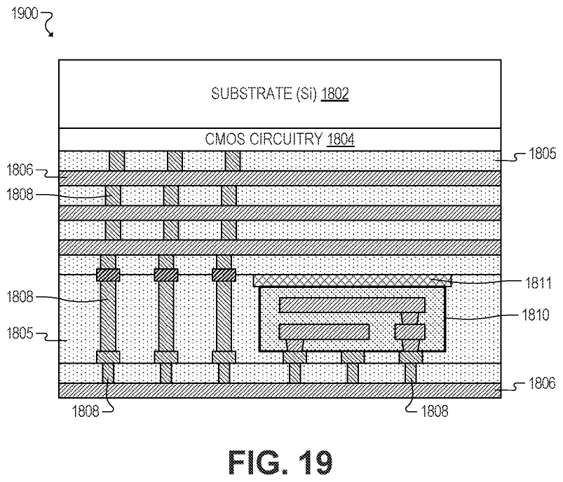

FIG. 19 illustrates an example 1900 of a passive RF dielet 1810 (e.g., containing a transformer) integrated with CMOS circuitry 1804 on a dielectric mesa 1811 without any interconnect capability to the CMOS circuitry 1804. For example, the dielet 1810 is selectively transferred using the process flow of FIGS. 1A-I (e.g., a single selective transfer directly from a donor substrate), and thus a dielectric mesa 1811 is present, but the mesa 1811 does not include any metal pads for HBI connectivity to the CMOS circuitry 1804. Rather, the dielet 1810 connects to the subsequent metals layers 1806 built on top of the dielet 1810 (which are below the dielet 1810 in the orientation shown). In this manner, the dielet 1810 has external connectivity, but no direct wired internal connectivity to the CMOS circuitry 1804. In some cases, for example if an inductor is transferred, the inductor may communicatively couple electromagnetically/wirelessly to another inductor in other layers 1805 (e.g., without any vias). The illustrated example implements a transformer, where one of its coils is monolithically integrated on the substrate 1802 and the other coil 1810 is integrated via selective transfer. The thickness of the dielectric mesa 1811 affects the distance between the two coils and hence the performance of the transformer.

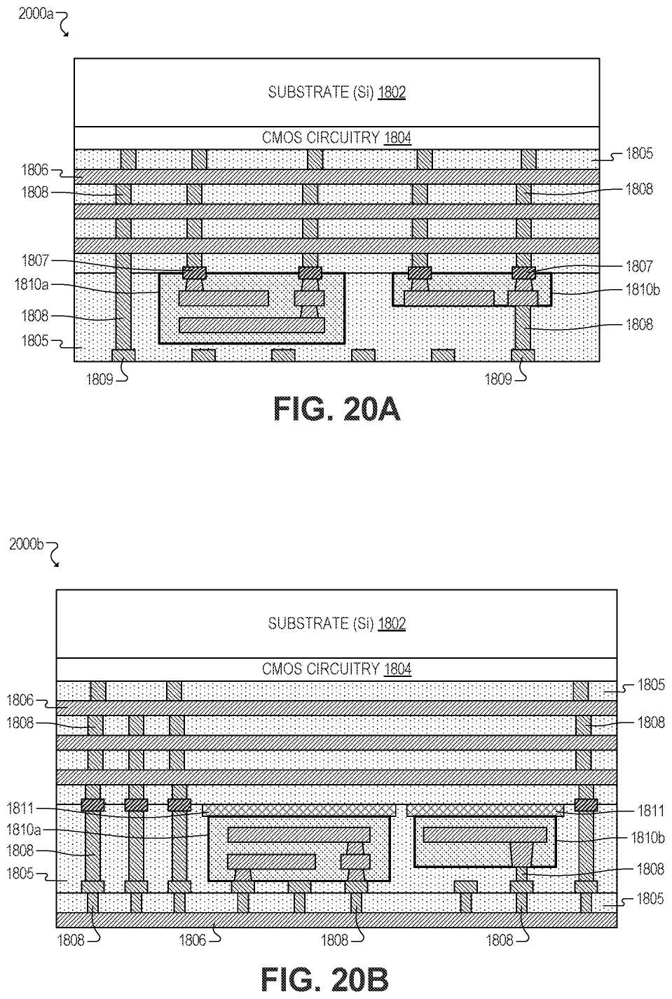

FIGS. 20A-B illustrate examples 2000a-b of multiple passive RF dielets 1810a-b (e.g., transformers, inductors) with different dimensions (e.g., thickness, area) integrated with CMOS circuitry 1804. In the illustrated examples, two dielets 1810a-b with different thicknesses and/or areas, which may optionally be fabricated using different processes (e.g., III-V and glass, respectively), are selectively transferred over the base substrate 1802. Via orientation in each dielet 1810a-b may be face up or face down, and in either orientation, the dielets 1810a-b may or may not be on dielectric or hybrid-bonded mesas, depending on the particular selective transfer process used. For example, in FIG. 20A, the dielets 1810a-b are selectively transferred and hybrid bonded to HBI pads 1807 to form an HBI interconnect to the CMOS circuitry 1804 (e.g., with no mesas). In FIG. 20B, the dielets 1810a-b are selectively transferred to dielectric mesas 1811, and additional metal 1806, 1808 and dielectric 1805 layers are built on top/over the transferred passive dielets 1810a-b (i.e., below the dielets 1810a-b in the orientation shown) for external connectivity.

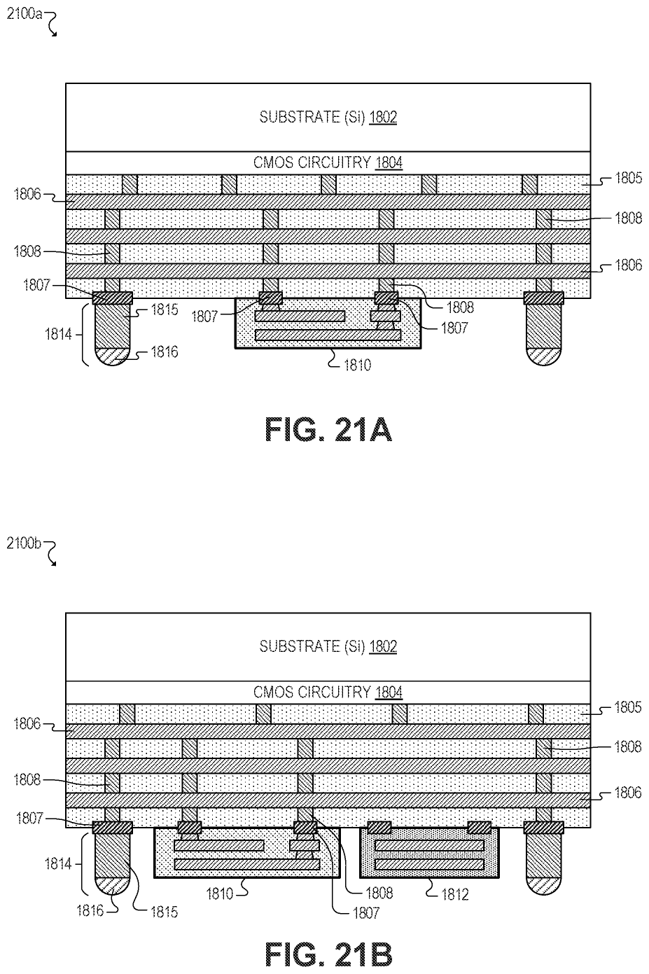

FIGS. 21A-B illustrate examples 2100a-b of dielets 1810, 1812 (e.g., transformers, inductors, antennas, waveguides, transmission lines) integrated with CMOS circuitry 1804 among bumps 1814. In the illustrated examples, the bumps 1814 include a metal (e.g., copper) pillar 1815 and solder dome 1816 and are connected to metal (e.g., copper) pads 1807. In some embodiments, the bumps 1814 may be chip connection (C2) bumps or controlled-collapse chip connection (C4) bumps. Moreover, the bumps 1814 may be used as an interconnect to an IC package or another component (not shown). Further, one or more dielets 1810, 1812 may be integrated among the bumps 1814 via selective transfer and interconnected with the CMOS circuitry 1804 via HBI pads 1807. In some cases, integrating dielets 1810, 1812 between bumps 1814 may be more efficient than integrating them within thin ILD layers 1805 (e.g., which may impose dense filling requirements).

In FIG. 21A, a dielet 1810 with passive RF circuitry is selectively transferred between bumps 1814 on the surface of the substrate 1802 layers and hybrid bonded to HBI pads 1807 to interconnect with the CMOS circuitry 1804.

In FIG. 21B, a dielet 1810 with passive RF circuitry is selectively transferred between the bumps 1814 along with a dummy dielet 1812. The dummy dielet 1812 may be a non-functional dielet (e.g., no electrical functionality) transferred with the functioning dielet 1810 to satisfy mechanical requirements of the design, such as structural stability, preventing warpage, etc.

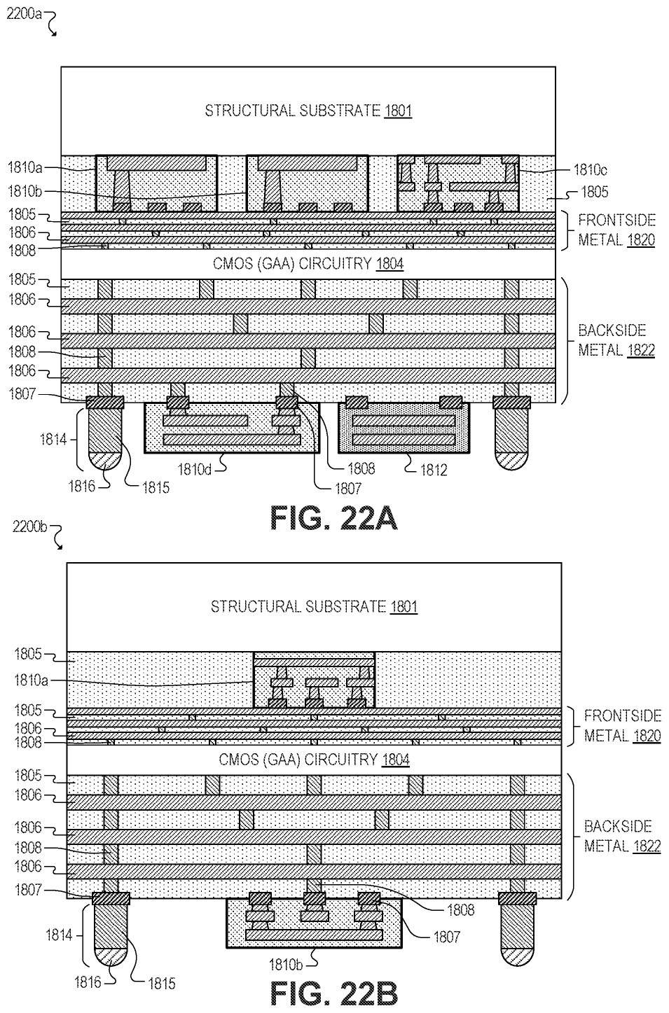

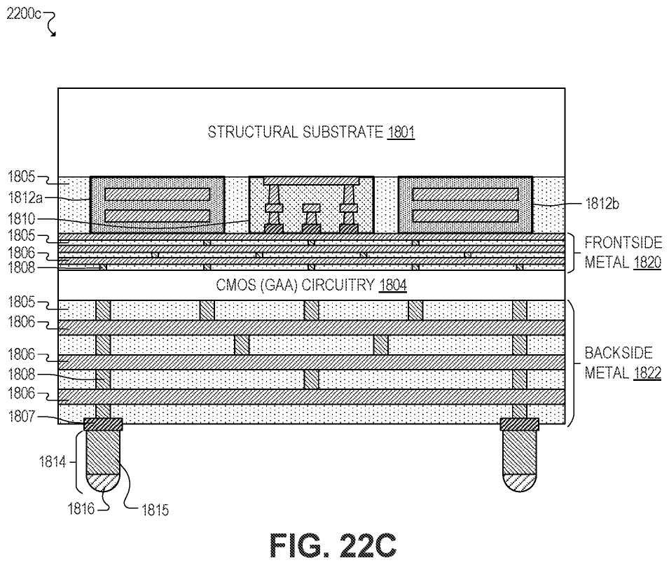

FIGS. 22A-C illustrate examples 2200a-c of dielets 1810, 1812 integrated with gate-all-around (GAA) CMOS circuitry 1804 on frontside metal (FSM) 1820 and/or backside metal (BSM) 1822 layers. In processes with frontside metal (FSM) 1820 and backside metal (BSM) 1822 layers, such as CMOS circuitry 1804 with GAA transistors/devices, it may be beneficial to integrate RF passives and RF transmission lines in the FSM stack 1820 and/or the BSM stack 1822. However, the FSM stack 1820 typically includes very thin metal layers 1806 (e.g., less than 1 μm thick) optimized for high-density routing, which makes integration within the FSM stack 1820 challenging. Accordingly, in the illustrated examples, dielets 1810 containing RF passives and RF transmission lines are integrated on the FSM stack 1820 (and the BSM stack 1822) via selective transfer. Moreover, a structural substrate 1801 is attached above the selectively-transferred dielets 1810 on the FSM stack 1820 to provide structural support.

In FIG. 22A, dielets 1810a-c containing thick antennas and/or inductors are selectively transferred on the FSM stack 1820 to provide routing for RF devices (e.g., GAA transistors) in the CMOS GAA circuitry 1804, thus enabling backside radiation (e.g., without the use of any through-silicon vias (TSVs)). In some cases, an additional ground (GND)/shielding plane can be part of the transferred die (e.g., as shown in dielet 1810c) to allow increased shielding from electromagnetic interference (EMI). Further, a dielet 1810d containing passive RF circuitry (e.g., a transformer) is integrated on the BSM stack 1822 via selective transfer, along with a dummy dielet 1812 for mechanical purposes.

In FIG. 22B, a dielet 1810a containing RF transmission lines (e.g., inverted microstrip lines, microstrip lines, striplines) is selectively transferred on the FSM stack 1820 to provide efficient low-loss routing on the frontside as an additional routing layer (e.g., to BSM 1822 interconnect layers 1806 and BSM transferred dies 1810b) between RF subsystems. Similarly, another dielet 1810b containing RF transmission lines is integrated on the BSM stack 1822 via selective transfer.

In FIG. 22C, a dielet 1810 containing a terahertz (THz) waveguide network is selectively transferred on the FSM stack 1820, along with two dummy dielets 1812a-b for mechanical purposes. As frequencies scale from 30+ gigahertz (GHz) (e.g., millimeter wave (mmWave)) to terahertz (THz) (e.g., sub-THz), the cross-sectional dimensions of waveguide structures (metallized or open) may approach close to 500 μm, which makes it challenging to integrate these waveguide networks in the FSM stack 1820 (or the BSM stack 1822). As a result, dielets containing THz waveguide networks (e.g., dielet 1810) may be integrated on the FSM stack 1820 and/or BSM stack 1822 via selective transfer. Such waveguide networks 1810 can be used as communication channels or as synchronization networks among several on-die subsystems.

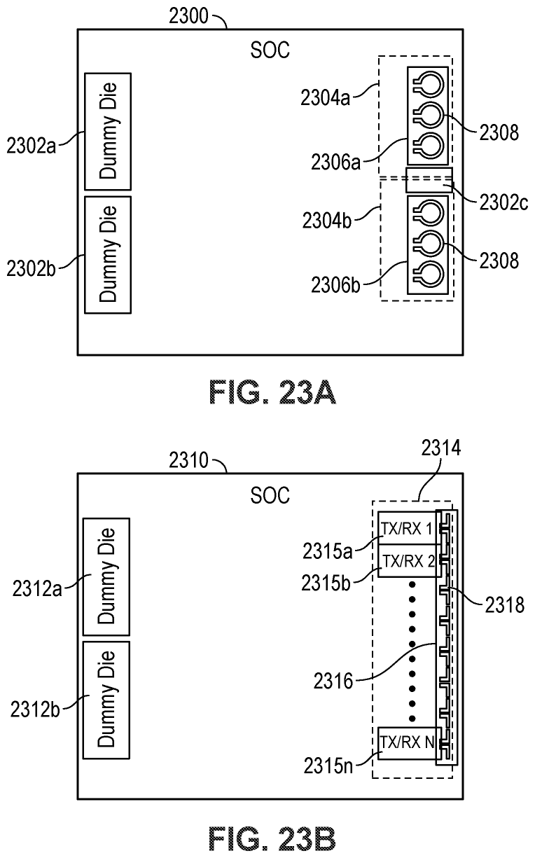

FIGS. 23A-B illustrate examples of systems-on-a-chip (SoCs) 2300, 2310 with input/output (I/O) and wireless components integrated on the periphery of the die/chip via selective transfer. In some embodiments, the SoCs 2300, 2310 may include processing circuitry (e.g., XPU, FPGA, ASIC on silicon) (not shown) that utilizes the I/O and/or wireless components for communication. In particular, FIG. 23A shows a plan view of an SoC 2300 with I/O components integrated via selective transfer, and FIG. 23B shows a plan view of an SoC 2310 with wireless-connectivity components integrated via selective transfer. Similar embodiments can be implemented for other related applications, such as optical I/O and THz/sub-THz waveguide I/O.

In FIG. 23A, the SoC 2300 includes multiple I/O ports 2304a-b (e.g., peripheral component interconnect express (PCIe), SerDes, and/or RF transceiver ports) on the periphery of the chip 2300, along with multiple dummy dies 2302a-c for mechanical purposes. The I/O ports 2304a-b include matching networks 2306a-b of passive components 2308, such as inductors (e.g., planar, magnetic core, vertical) and capacitors (e.g., planar, deep trench capacitors (DTCs), metal-insulator-metal (MIM)), which may have a width of approximately 100-500 μm. In the illustrated embodiment, the matching networks 2306a-b are implemented on dielets and selectively transferred to the periphery of the chip 2300 (e.g., among bumps (e.g., C4 bumps) or on the backside metal (BSM) stack). In some embodiments, the dummy dies 2302a-c may also be integrated via selective transfer.

In FIG. 23B, the SoC 2310 includes a wireless transceiver interface 2314 on the periphery of the chip (e.g., for chip-to-chip communication), along with multiple dummy dies 2312a-b for mechanical purposes. The transceiver interface 2314 includes multiple transmit and receive (TX/RX) lanes 2315a-n coupled to antennas 2318 on the periphery of the chip 2310 for chip-to-chip communication. In some embodiments, the antennas 2318 may have widths ranging from 100-800 μm and may span all or part of the edge of the chip 2310. In the illustrated embodiment, the antennas 2318 are implemented on a dielet 2316, which is integrated on the periphery of the chip 2310 via selective transfer. In some embodiments, the dummy dies 2312a-b may also be integrated via selective transfer.

### Process Flow for Integrating RF, High-Voltage, Varactor, Group III-V, and Passive Devices

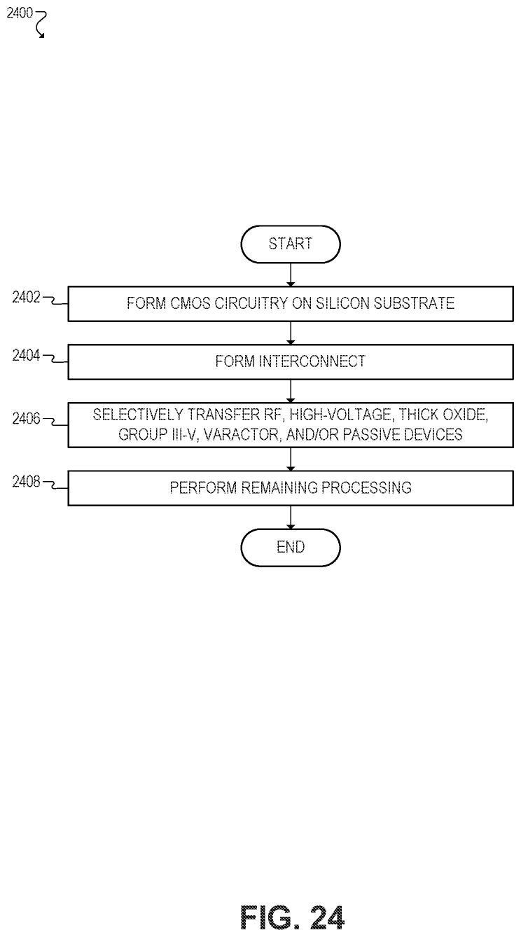

FIG. 24 illustrates a flowchart 2400 for integrating radio frequency (RF) components (e.g., high-voltage, thick oxide, Group III-V, varactor, and/or passive devices and components) with silicon CMOS circuitry using selective transfer technology. In some embodiments, for example, flowchart 2400 may be used to form the example devices and systems of FIGS. 8-23. It will be appreciated in light of the present disclosure that the illustrated process flow is only one example methodology for integrating the respective devices using selective transfer technology. Moreover, in various embodiments, the steps of the illustrated process flow may be performed using any suitable semiconductor fabrication techniques.

The flowchart begins at block 2402 by forming CMOS devices and circuitry on a silicon substrate (e.g., PMOS/NMOS transistors, logic circuitry, digital circuitry, memory circuitry, etc.).

The flowchart then proceeds to block 2404 to form an interconnect over the silicon CMOS device layer (e.g., by forming dielectric layers and metallization layers and patterning them into traces and vias).

The flowchart then proceeds to block 2406 to selectively transfer one or more RF, high-voltage, thick oxide, Group III-V, varactor, and/or passive devices or components (e.g., thick oxide transistors, Group III-V transistors, varactors, high-voltage ESDs, RF antennas, interconnects, inductors, transformers, passives, etc.) from one or more donor substrates (e.g., using the selective transfer technology described in connection with FIGS. 1-7).

The flowchart then proceeds to block 2408 to perform any remaining processing, such as dielectric filling and planarization, attaching additional IC dies or components (e.g., via selective transfers or pick-and-place assembly), placement of dummy dies for mechanical purposes (e.g., via selective transfer or pick-and-place), forming additional interconnects (e.g., vias, traces), attaching a structural substrate, and/or any other processing required for the finished product (e.g., an IC package, device, system, etc.).

At this point, the flowchart may be complete. In some embodiments, however, the flowchart may restart and/or certain blocks may be repeated. For example, in some embodiments, the flowchart may restart at block 2402 to continue integrating RF components using selective transfer technology.

### Example Embodiments

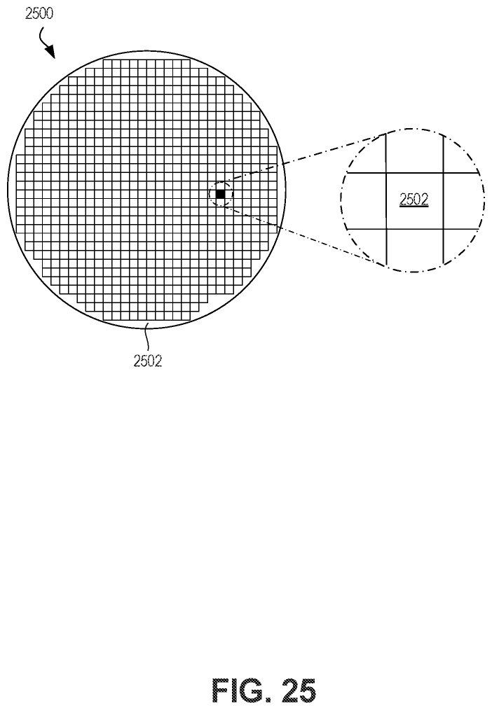

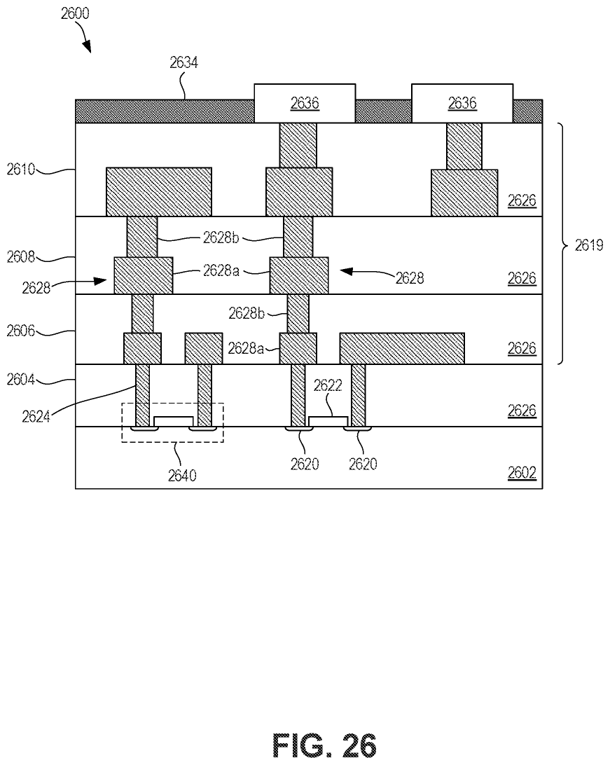

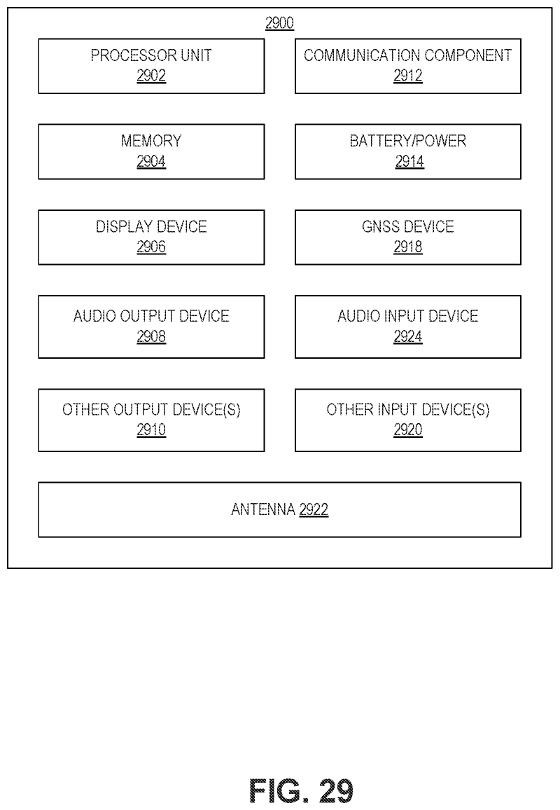

FIG. 25 is a top view of a wafer 2500 and dies 2502 that may be included in any of the embodiments disclosed herein. The wafer 2500 may be composed of semiconductor material and may include one or more dies 2502 having integrated circuit structures formed on a surface of the wafer 2500. The individual dies 2502 may be a repeating unit of an integrated circuit product that includes any suitable integrated circuit. After the fabrication of the semiconductor product is complete, the wafer 2500 may undergo a singulation process in which the dies 2502 are separated from one another to provide discrete “chips” of the integrated circuit product. The die 2502 may be any of the dies disclosed herein. The die 2502 may include one or more transistors (e.g., some of the transistors 2640 of FIG. 26, discussed below), supporting circuitry to route electrical signals to the transistors, passive components (e.g., signal traces, resistors, capacitors, or inductors), and/or any other integrated circuit components. In some embodiments, the wafer 2500 or the die 2502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 2502. For example, a memory array formed by multiple memory devices may be formed on a same die 2502 as a processor unit (e.g., the processor unit 2902 of FIG. 29) or other logic that is configured to store information in the memory devices or execute instructions stored in the memory array. Various ones of the microelectronic assemblies disclosed herein may be manufactured using a die-to-wafer assembly technique in which some dies are attached to a wafer 2500 that include others of the dies, and the wafer 2500 is subsequently singulated.

FIG. 26 is a cross-sectional side view of an integrated circuit device 2600 that may be included in any of the embodiments disclosed herein (e.g., in any of the dies). One or more of the integrated circuit devices 2600 may be included in one or more dies 2502 (FIG. 25). The integrated circuit device 2600 may be formed on a die substrate 2602 (e.g., the wafer 2500 of FIG. 25) and may be included in a die (e.g., the die 2502 of FIG. 25). The die substrate 2602 may be a semiconductor substrate composed of semiconductor material systems including, for example, n-type or p-type materials systems (or a combination of both). The die substrate 2602 may include, for example, a crystalline substrate formed using a bulk silicon or a silicon-on-insulator (SOI) substructure. In some embodiments, the die substrate 2602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 2602. Although a few examples of materials from which the die substrate 2602 may be formed are described here, any material that may serve as a foundation for an integrated circuit device 2600 may be used. The die substrate 2602 may be part of a singulated die (e.g., the dies 2502 of FIG. 25) or a wafer (e.g., the wafer 2500 of FIG. 25).

The integrated circuit device 2600 may include one or more device layers 2604 disposed on the die substrate 2602. The device layer 2604 may include features of one or more transistors 2640 (e.g., metal oxide semiconductor field-effect transistors (MOSFETs)) formed on the die substrate 2602. The transistors 2640 may include, for example, one or more source and/or drain (S/D) regions 2620, a gate 2622 to control current flow between the S/D regions 2620, and one or more S/D contacts 2624 to route electrical signals to/from the S/D regions 2620. The transistors 2640 may include additional features not depicted for the sake of clarity, such as device isolation regions, gate contacts, and the like. The transistors 2640 are not limited to the type and configuration depicted in FIG. 26 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

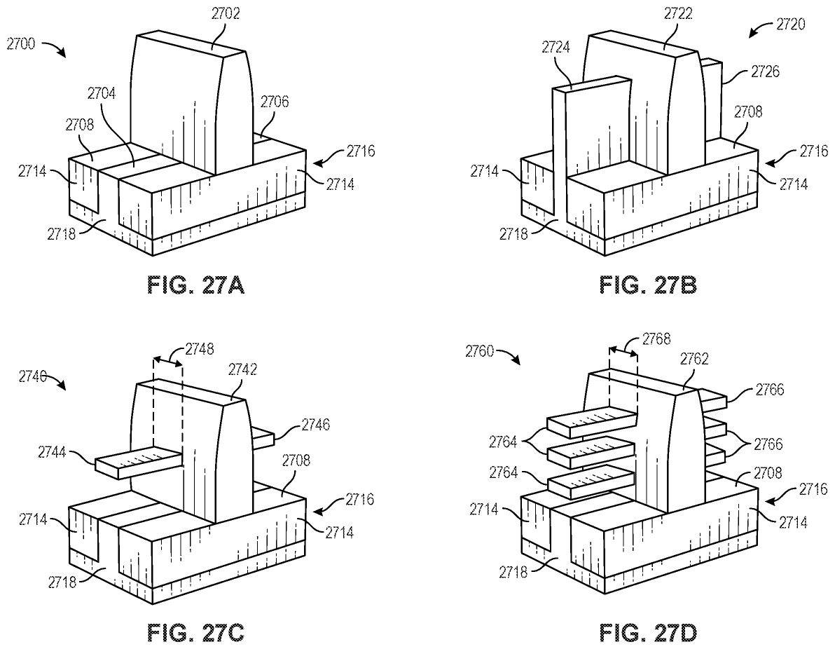

FIGS. 27A-D are simplified perspective views of example planar, FinFET, gate-all-around, and stacked gate-all-around transistors that may be included in any of the embodiments disclosed herein (e.g., in any of the dies). The transistors illustrated in FIGS. 27A-27D are formed on a substrate 2716 having a surface 2708. Isolation regions 2714 separate the source and drain regions of the transistors from other transistors and from a bulk region 2718 of the substrate 2716.

FIG. 27A is a perspective view of an example planar transistor 2700 comprising a gate 2702 that controls current flow between a source region 2704 and a drain region 2706. The transistor 2700 is planar in that the source region 2704 and the drain region 2706 are planar with respect to the substrate surface 2708.

FIG. 27B is a perspective view of an example FinFET transistor 2720 comprising a gate 2722 that controls current flow between a source region 2724 and a drain region 2726. The transistor 2720 is non-planar in that the source region 2724 and the drain region 2726 comprise “fins” that extend upwards from the substrate surface 2728. As the gate 2722 encompasses three sides of the semiconductor fin that extends from the source region 2724 to the drain region 2726, the transistor 2720 can be considered a tri-gate transistor. FIG. 27B illustrates one S/D fin extending through the gate 2722, but multiple S/D fins can extend through the gate of a FinFET transistor.

FIG. 27C is a perspective view of a gate-all-around (GAA) transistor 2740 comprising a gate 2742 that controls current flow between a source region 2744 and a drain region 2746. The transistor 2740 is non-planar in that the source region 2744 and the drain region 2746 are elevated from the substrate surface 2728.

FIG. 27D is a perspective view of a GAA transistor 2760 comprising a gate 2762 that controls current flow between multiple elevated source regions 2764 and multiple elevated drain regions 2766. The transistor 2760 is a stacked GAA transistor as the gate controls the flow of current between multiple elevated S/D regions stacked on top of each other. The transistors 2740 and 2760 are considered gate-all-around transistors as the gates encompass all sides of the semiconductor portions that extends from the source regions to the drain regions. The transistors 2740 and 2760 can alternatively be referred to as nanowire, nanosheet, or nanoribbon transistors depending on the width (e.g., widths 2748 and 2768 of transistors 2740 and 2760, respectively) of the semiconductor portions extending through the gate.

Returning to FIG. 26, a transistor 2640 may include a gate 2622 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 2640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 2640 along the source-channel-drain direction, the gate electrode may consist of a U-shaped structure that includes a bottom portion substantially parallel to the surface of the die substrate 2602 and two sidewall portions that are substantially perpendicular to the top surface of the die substrate 2602. In other embodiments, at least one of the metal layers that form the gate electrode may simply be a planar layer that is substantially parallel to the top surface of the die substrate 2602 and does not include sidewall portions substantially perpendicular to the top surface of the die substrate 2602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 2620 may be formed within the die substrate 2602 adjacent to the gate 2622 of individual transistors 2640. The S/D regions 2620 may be formed using an implantation/diffusion process or an etching/deposition process, for example. In the former process, dopants such as boron, aluminum, antimony, phosphorous, or arsenic may be ion-implanted into the die substrate 2602 to form the S/D regions 2620. An annealing process that activates the dopants and causes them to diffuse farther into the die substrate 2602 may follow the ion-implantation process. In the latter process, the die substrate 2602 may first be etched to form recesses at the locations of the S/D regions 2620. An epitaxial deposition process may then be carried out to fill the recesses with material that is used to fabricate the S/D regions 2620. In some implementations, the S/D regions 2620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 2620 may be formed using one or more alternate semiconductor materials such as germanium or a group III-V material or alloy. In further embodiments, one or more layers of metal and/or metal alloys may be used to form the S/D regions 2620.

Electrical signals, such as power and/or input/output (I/O) signals, may be routed to and/or from the devices (e.g., transistors 2640) of the device layer 2604 through one or more interconnect layers disposed on the device layer 2604 (illustrated in FIG. 26 as interconnect layers 2606-2610). For example, electrically conductive features of the device layer 2604 (e.g., the gate 2622 and the S/D contacts 2624) may be electrically coupled with the interconnect structures 2628 of the interconnect layers 2606-2610. The one or more interconnect layers 2606-2610 may form a metallization stack (also referred to as an “ILD stack”) 2619 of the integrated circuit device 2600.

The interconnect structures 2628 may be arranged within the interconnect layers 2606-2610 to route electrical signals according to a wide variety of designs; in particular, the arrangement is not limited to the particular configuration of interconnect structures 2628 depicted in FIG. 26. Although a particular number of interconnect layers 2606-2610 is depicted in FIG. 26, embodiments of the present disclosure include integrated circuit devices having more or fewer interconnect layers than depicted.

In some embodiments, the interconnect structures 2628 may include lines 2628a and/or vias 2628b filled with an electrically conductive material such as a metal. The lines 2628a may be arranged to route electrical signals in a direction of a plane that is substantially parallel with a surface of the die substrate 2602 upon which the device layer 2604 is formed. For example, the lines 2628a may route electrical signals in a direction in and out of the page and/or in a direction across the page from the perspective of FIG. 26. The vias 2628b may be arranged to route electrical signals in a direction of a plane that is substantially perpendicular to the surface of the die substrate 2602 upon which the device layer 2604 is formed. In some embodiments, the vias 2628b may electrically couple lines 2628a of different interconnect layers 2606-2610 together.

The interconnect layers 2606-2610 may include a dielectric material 2626 disposed between the interconnect structures 2628, as shown in FIG. 26. In some embodiments, dielectric material 2626 disposed between the interconnect structures 2628 in different ones of the interconnect layers 2606-2610 may have different compositions; in other embodiments, the composition of the dielectric material 2626 between different interconnect layers 2606-2610 may be the same. The device layer 2604 may include a dielectric material 2626 disposed between the transistors 2640 and a bottom layer of the metallization stack as well. The dielectric material 2626 included in the device layer 2604 may have a different composition than the dielectric material 2626 included in the interconnect layers 2606-2610; in other embodiments, the composition of the dielectric material 2626 in the device layer 2604 may be the same as a dielectric material 2626 included in any one of the interconnect layers 2606-2610.

A first interconnect layer 2606 (referred to as Metal 1 or “M1”) may be formed directly on the device layer 2604. In some embodiments, the first interconnect layer 2606 may include lines 2628a and/or vias 2628b, as shown. The lines 2628a of the first interconnect layer 2606 may be coupled with contacts (e.g., the S/D contacts 2624) of the device layer 2604. The vias 2628b of the first interconnect layer 2606 may be coupled with the lines 2628a of a second interconnect layer 2608.

The second interconnect layer 2608 (referred to as Metal 2 or “M2”) may be formed directly on the first interconnect layer 2606. In some embodiments, the second interconnect layer 2608 may include via 2628b to couple the lines 2628 of the second interconnect layer 2608 with the lines 2628a of a third interconnect layer 2610. Although the lines 2628a and the vias 2628b are structurally delineated with a line within individual interconnect layers for the sake of clarity, the lines 2628a and the vias 2628b may be structurally and/or materially contiguous (e.g., simultaneously filled during a dual-damascene process) in some embodiments.

The third interconnect layer 2610 (referred to as Metal 3 or “M3”) (and additional interconnect layers, as desired) may be formed in succession on the second interconnect layer 2608 according to similar techniques and configurations described in connection with the second interconnect layer 2608 or the first interconnect layer 2606. In some embodiments, the interconnect layers that are “higher up” in the metallization stack 2619 in the integrated circuit device 2600 (i.e., farther away from the device layer 2604) may be thicker that the interconnect layers that are lower in the metallization stack 2619, with lines 2628a and vias 2628b in the higher interconnect layers being thicker than those in the lower interconnect layers.

The integrated circuit device 2600 may include a solder resist material 2634 (e.g., polyimide or similar material) and one or more conductive contacts 2636 formed on the interconnect layers 2606-2610. In FIG. 26, the conductive contacts 2636 are illustrated as taking the form of bond pads. The conductive contacts 2636 may be electrically coupled with the interconnect structures 2628 and configured to route the electrical signals of the transistor(s) 2640 to external devices. For example, solder bonds may be formed on the one or more conductive contacts 2636 to mechanically and/or electrically couple an integrated circuit die including the integrated circuit device 2600 with another component (e.g., a printed circuit board). The integrated circuit device 2600 may include additional or alternate structures to route the electrical signals from the interconnect layers 2606-2610; for example, the conductive contacts 2636 may include other analogous features (e.g., posts) that route the electrical signals to external components. The conductive contacts 2636 may serve as any of the conductive contacts described throughout this disclosure.

In some embodiments in which the integrated circuit device 2600 is a double-sided die, the integrated circuit device 2600 may include another metallization stack (not shown) on the opposite side of the device layer(s) 2604. This metallization stack may include multiple interconnect layers as discussed above with reference to the interconnect layers 2606-2610, to provide conductive pathways (e.g., including conductive lines and vias) between the device layer(s) 2604 and additional conductive contacts (not shown) on the opposite side of the integrated circuit device 2600 from the conductive contacts 2636. These additional conductive contacts may serve as any of the conductive contacts described throughout this disclosure.

In other embodiments in which the integrated circuit device 2600 is a double-sided die, the integrated circuit device 2600 may include one or more through silicon vias (TSVs) through the die substrate 2602; these TSVs may make contact with the device layer(s) 2604, and may provide conductive pathways between the device layer(s) 2604 and additional conductive contacts (not shown) on the opposite side of the integrated circuit device 2600 from the conductive contacts 2636. These additional conductive contacts may serve as any of the conductive contacts described throughout this disclosure. In some embodiments, TSVs extending through the substrate can be used for routing power and ground signals from conductive contacts on the opposite side of the integrated circuit device 2600 from the conductive contacts 2636 to the transistors 2640 and any other components integrated into the die 2600, and the metallization stack 2619 can be used to route I/O signals from the conductive contacts 2636 to transistors 2640 and any other components integrated into the die 2600.

Multiple integrated circuit devices 2600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

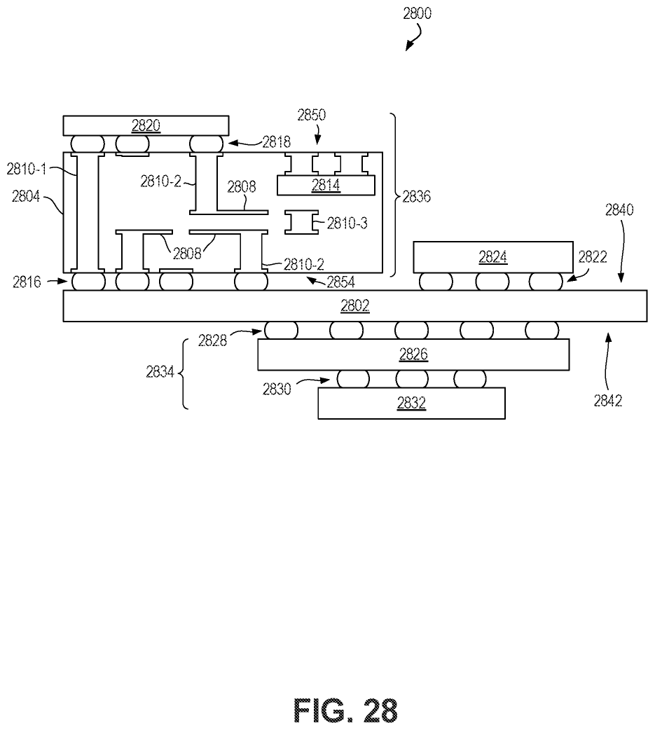

FIG. 28 is a cross-sectional side view of an integrated circuit device assembly 2800 that may include any of the embodiments disclosed herein (e.g., RF, high-voltage, varactor, Group III-V, and/or passive components selectively transferred from donor wafers). In some embodiments, the integrated circuit device assembly 2800 may be a microelectronic assembly. The integrated circuit device assembly 2800 includes a number of components disposed on a circuit board 2802 (which may be a motherboard, system board, mainboard, etc.). The integrated circuit device assembly 2800 includes components disposed on a first face 2840 of the circuit board 2802 and an opposing second face 2842 of the circuit board 2802; generally, components may be disposed on one or both faces 2840 and 2842. Any of the integrated circuit components discussed below with reference to the integrated circuit device assembly 2800 may take the form of any suitable ones of the embodiments of the microelectronic assemblies 100 disclosed herein.

In some embodiments, the circuit board 2802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 2802. In other embodiments, the circuit board 2802 may be a non-PCB substrate. The integrated circuit device assembly 2800 illustrated in FIG. 28 includes a package-on-interposer structure 2836 coupled to the first face 2840 of the circuit board 2802 by coupling components 2816. The coupling components 2816 may electrically and mechanically couple the package-on-interposer structure 2836 to the circuit board 2802, and may include solder balls (as shown in FIG. 28), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 2816 may serve as the coupling components illustrated or described for any of the substrate assembly or substrate assembly components described herein, as appropriate.

The package-on-interposer structure 2836 may include an integrated circuit component 2820 coupled to an interposer 2804 by coupling components 2818. The coupling components 2818 may take any suitable form for the application, such as the forms discussed above with reference to the coupling components 2816. Although a single integrated circuit component 2820 is shown in FIG. 28, multiple integrated circuit components may be coupled to the interposer 2804; indeed, additional interposers may be coupled to the interposer 2804. The interposer 2804 may provide an intervening substrate used to bridge the circuit board 2802 and the integrated circuit component 2820.

The integrated circuit component 2820 may be a packaged or unpackaged integrated circuit product that includes one or more integrated circuit dies (e.g., the die 2502 of FIG. 25, the integrated circuit device 2600 of FIG. 26) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 2820, a single monolithic integrated circuit die comprises solder bumps attached to contacts on the die. The solder bumps allow the die to be directly attached to the interposer 2804. The integrated circuit component 2820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 2820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 2820 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 2820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 2804 may spread connections to a wider pitch or reroute a connection to a different connection. For example, the interposer 2804 may couple the integrated circuit component 2820 to a set of ball grid array (BGA) conductive contacts of the coupling components 2816 for coupling to the circuit board 2802. In the embodiment illustrated in FIG. 28, the integrated circuit component 2820 and the circuit board 2802 are attached to opposing sides of the interposer 2804; in other embodiments, the integrated circuit component 2820 and the circuit board 2802 may be attached to a same side of the interposer 2804. In some embodiments, three or more components may be interconnected by way of the interposer 2804.

In some embodiments, the interposer 2804 may be formed as a PCB, including multiple metal layers separated from one another by layers of dielectric material and interconnected by electrically conductive vias. In some embodiments, the interposer 2804 may be formed of an epoxy resin, a fiberglass-reinforced epoxy resin, an epoxy resin with inorganic fillers, a ceramic material, or a polymer material such as polyimide. In some embodiments, the interposer 2804 may be formed of alternate rigid or flexible materials that may include the same materials described above for use in a semiconductor substrate, such as silicon, germanium, and other group III-V and group IV materials. The interposer 2804 may include metal interconnects 2808 and vias 2810, including but not limited to through hole vias 2810-1 (that extend from a first face 2850 of the interposer 2804 to a second face 2854 of the interposer 2804), blind vias 2810-2 (that extend from the first or second faces 2850 or 2854 of the interposer 2804 to an internal metal layer), and buried vias 2810-3 (that connect internal metal layers).

In some embodiments, the interposer 2804 can comprise a silicon interposer. Through silicon vias (TSV) extending through the silicon interposer can connect connections on a first face of a silicon interposer to an opposing second face of the silicon interposer. In some embodiments, an interposer 2804 comprising a silicon interposer can further comprise one or more routing layers to route connections on a first face of the interposer 2804 to an opposing second face of the interposer 2804.

The interposer 2804 may further include embedded devices 2814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2804. The package-on-interposer structure 2836 may take the form of any of the package-on-interposer structures known in the art. In embodiments where the interposer is a non-printed circuit board

The integrated circuit device assembly 2800 may include an integrated circuit component 2824 coupled to the first face 2840 of the circuit board 2802 by coupling components 2822. The coupling components 2822 may take the form of any of the embodiments discussed above with reference to the coupling components 2816, and the integrated circuit component 2824 may take the form of any of the embodiments discussed above with reference to the integrated circuit component 2820.

The integrated circuit device assembly 2800 illustrated in FIG. 28 includes a package-on-package structure 2834 coupled to the second face 2842 of the circuit board 2802 by coupling components 2828. The package-on-package structure 2834 may include an integrated circuit component 2826 and an integrated circuit component 2832 coupled together by coupling components 2830 such that the integrated circuit component 2826 is disposed between the circuit board 2802 and the integrated circuit component 2832. The coupling components 2828 and 2830 may take the form of any of the embodiments of the coupling components 2816 discussed above, and the integrated circuit components 2826 and 2832 may take the form of any of the embodiments of the integrated circuit component 2820 discussed above. The package-on-package structure 2834 may be configured in accordance with any of the package-on-package structures known in the art.

FIG. 29 is a block diagram of an example electrical device 2900 that may include one or more of the embodiments disclosed herein. For example, any suitable ones of the components of the electrical device 2900 may include one or more selectively transferred RF, high-voltage, varactor, Group III-V, and/or passive components, integrated circuit dies, integrated circuit device assemblies 2800, integrated circuit components 2820, integrated circuit devices 2600, or integrated circuit dies 2502 disclosed herein. A number of components are illustrated in FIG. 29 as included in the electrical device 2900, but any one or more of these components may be omitted or duplicated, as suitable for the application. In some embodiments, some or all of the components included in the electrical device 2900 may be attached to one or more motherboards mainboards, or system boards. In some embodiments, one or more of these components are fabricated onto a single system-on-a-chip (SoC) die.

Additionally, in various embodiments, the electrical device 2900 may not include one or more of the components illustrated in FIG. 29, but the electrical device 2900 may include interface circuitry for coupling to the one or more components. For example, the electrical device 2900 may not include a display device 2906, but may include display device interface circuitry (e.g., a connector and driver circuitry) to which a display device 2906 may be coupled. In another set of examples, the electrical device 2900 may not include an audio input device 2924 or an audio output device 2908, but may include audio input or output device interface circuitry (e.g., connectors and supporting circuitry) to which an audio input device 2924 or audio output device 2908 may be coupled.

The electrical device 2900 may include one or more processor units 2902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 2902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 2900 may include a memory 2904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 2904 may include memory that is located on the same integrated circuit die as the processor unit 2902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 2900 can comprise one or more processor units 2902 that are heterogeneous or asymmetric to another processor unit 2902 in the electrical device 2900. There can be a variety of differences between the processing units 2902 in a system in terms of a spectrum of metrics of merit including architectural, microarchitectural, thermal, power consumption characteristics, and the like. These differences can effectively manifest themselves as asymmetry and heterogeneity among the processor units 2902 in the electrical device 2900.

In some embodiments, the electrical device 2900 may include a communication component 2912 (e.g., one or more communication components). For example, the communication component 2912 can manage wireless communications for the transfer of data to and from the electrical device 2900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 2912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 2912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 2912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 2912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 2912 may operate in accordance with other wireless protocols in other embodiments. The electrical device 2900 may include an antenna 2922 to facilitate wireless communications and/or to receive other wireless communications (such as AM or FM radio transmissions).

In some embodiments, the communication component 2912 may manage wired communications, such as electrical, optical, or any other suitable communication protocols (e.g., IEEE 802.3 Ethernet standards). As noted above, the communication component 2912 may include multiple communication components. For instance, a first communication component 2912 may be dedicated to shorter-range wireless communications such as Wi-Fi or Bluetooth, and a second communication component 2912 may be dedicated to longer-range wireless communications such as global positioning system (GPS), EDGE, GPRS, CDMA, WiMAX, LTE, EV-DO, or others. In some embodiments, a first communication component 2912 may be dedicated to wireless communications, and a second communication component 2912 may be dedicated to wired communications.

The electrical device 2900 may include battery/power circuitry 2914. The battery/power circuitry 2914 may include one or more energy storage devices (e.g., batteries or capacitors) and/or circuitry for coupling components of the electrical device 2900 to an energy source separate from the electrical device 2900 (e.g., AC line power).

The electrical device 2900 may include a display device 2906 (or corresponding interface circuitry, as discussed above). The display device 2906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 2900 may include an audio output device 2908 (or corresponding interface circuitry, as discussed above). The audio output device 2908 may include any embedded or wired or wirelessly connected external device that generates an audible indicator, such speakers, headsets, or earbuds.

The electrical device 2900 may include an audio input device 2924 (or corresponding interface circuitry, as discussed above). The audio input device 2924 may include any embedded or wired or wirelessly connected device that generates a signal representative of a sound, such as microphones, microphone arrays, or digital instruments (e.g., instruments having a musical instrument digital interface (MIDI) output). The electrical device 2900 may include a Global Navigation Satellite System (GNSS) device 2918 (or corresponding interface circuitry, as discussed above), such as a Global Positioning System (GPS) device. The GNSS device 2918 may be in communication with a satellite-based system and may determine a geolocation of the electrical device 2900 based on information received from one or more GNSS satellites, as known in the art.

The electrical device 2900 may include other output device(s) 2910 (or corresponding interface circuitry, as discussed above). Examples of the other output device(s) 2910 may include an audio codec, a video codec, a printer, a wired or wireless transmitter for providing information to other devices, or an additional storage device.

The electrical device 2900 may include other input device(s) 2920 (or corresponding interface circuitry, as discussed above). Examples of the other input device(s) 2920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 2900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 2900 may be any other electronic device that processes data. In some embodiments, the electrical device 2900 may comprise multiple discrete physical components. Given the range of devices that the electrical device 2900 can be manifested as in various embodiments, in some embodiments, the electrical device 2900 can be referred to as a computing device or a computing system.

### EXAMPLES

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a microelectronic assembly, comprising: a substrate comprising silicon; complementary metal-oxide-semiconductor (CMOS) circuitry over the substrate; and an integrated circuit (IC) die over the CMOS circuitry, wherein the IC die comprises one or more passive radio frequency (RF) components, and wherein the IC die has a thickness of 5 micrometers (μm) or less.

Example 2 includes the microelectronic assembly of Example 1, wherein the one or more passive RF components include at least one of an antenna, an interconnect, an inductor, a capacitor, or a transformer.

Example 3 includes the microelectronic assembly of any of Examples 1-2, wherein: the IC die is within a metal stack; the IC die is on a metal stack; or the IC die is between a plurality of interconnect bumps.

Example 4 includes the microelectronic assembly of any of Examples 1-3, wherein the IC die is electrically coupled to the CMOS circuitry via a hybrid-bonded interconnect.

Example 5 includes the microelectronic assembly of any of Examples 1-4, wherein the IC die has an area of less than 1 millimeter (mm)².

Example 6 includes the microelectronic assembly of any of Examples 1-5, further comprising a mesa structure under the IC die, wherein the mesa structure has a similar footprint as the IC die, and wherein the mesa structure comprises at least one of a dielectric material or a metal.

Example 7 includes the microelectronic assembly of any of Examples 1-6, further comprising a dummy die, wherein the dummy die has no electrical functionality.

Example 8 includes the microelectronic assembly of any of Examples 1-7, further comprising an RF transceiver, wherein the RF transceiver comprises the CMOS circuitry and the IC die.

Example 9 includes an electronic device, comprising: complementary metal-oxide-semiconductor (CMOS) circuitry; and a plurality of integrated circuit (IC) components, wherein the plurality of IC components include one or more antennas, interconnects, inductors, capacitors, and transformers, wherein at least one of the IC components is comprised in an IC die, wherein the IC die is on an adhesive area having a similar footprint as the IC die.

Example 10 includes the electronic device of Example 9, wherein the adhesive area comprises a mesa structure under the IC die, wherein the mesa structure has a similar footprint as the IC die, and wherein the mesa structure comprises at least one of a dielectric material or a metal.

Example 11 includes the electronic device of any of Examples 9-10, wherein the one or more interconnects include a terahertz waveguide network, wherein the terahertz waveguide network is comprised in the IC die.

Example 12 includes the electronic device of any of Examples 9-11, wherein the CMOS circuitry comprises one or more gate-all-around transistors.

Example 13 includes the electronic device of any of Examples 9-12, further comprising a radio frequency (RF) transceiver, wherein the RF transceiver comprises the CMOS circuitry and the plurality of IC components.

Example 14 includes the electronic device of Example 13, wherein: the electronic device further comprises a processing unit, wherein the processing unit is a central processing unit, a graphics processing unit, an application-specific integrated circuit, or a field-programmable gate array; and the RF transceiver is to send and receive RF signals on behalf of the processing unit.

Example 15 includes a method, comprising: receiving a first substrate, wherein the first substrate comprises a release layer and a layer of integrated circuit (IC) components over the release layer, wherein the layer of IC components comprises one or more antennas, interconnects, inductors, capacitors, or transformers; receiving a second substrate, wherein the second substrate comprises one or more adhesive areas; partially bonding the first substrate to the second substrate, wherein one or more IC components on the first substrate are bonded to the one or more adhesive areas on the second substrate, wherein the one or more IC components are from the layer of IC components; and separating the first substrate from the second substrate, wherein the one or more IC components are separated from the first substrate and remain on the second substrate.

Example 16 includes the method of Example 15, wherein the second substrate further comprises complementary metal-oxide-semiconductor (CMOS) circuitry.

Example 17 includes the method of any of Examples 15-16, further comprising, before separating the first substrate from the second substrate: exposing the release layer to electromagnetic radiation from a laser.

Example 18 includes the method of any of Examples 15-17, wherein the release layer comprises at least one of a metallic layer or a dielectric layer.

Example 19 includes the method of any of Examples 15-18, wherein the one or more adhesive areas include one or more raised structures, wherein the one or more raised structures comprise at least one of a dielectric material or a metal.

Example 20 includes the method of any of Examples 15-19, wherein receiving the first substrate comprises forming the first substrate, wherein forming the first substrate comprises: receiving a base substrate; forming the release layer over the base substrate; forming or transferring the layer of IC components over the release layer; and partially singulating the layer of IC components.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “under”, “between”, “adjacent”, “to”, and “on” as used herein may refer to a relative position of one layer or component with respect to other layers or components. For example, one layer “over”, “under”, or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views.

The term “package” generally refers to a self-contained carrier of one or more dice, where the dice are attached to or embedded in the package substrate, and may be encapsulated for protection, with integrated or wire-bonded interconnects between the dice, along with leads, pins, or bumps located on the external portions of the package substrate. The package may contain a single die, or multiple dice, providing respective functions. The package may be mounted on a printed circuit board for interconnection with other packaged integrated circuits and discrete components, forming a larger circuit.

The term “cored” generally refers to a substrate of an integrated circuit package built upon a board, card, or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core may allow for higher-density package architectures, as the through-vias may have relatively large dimensions and pitch compared to high-density interconnects.

The term “land side” generally refers to the side of the substrate of the integrated circuit package closest to the plane of attachment to a printed circuit board, motherboard, or other package. This is in contrast to the term “die side”, which generally refers to the side of the substrate of the integrated circuit package to which the die or dice are attached.

The terms “dielectric” and “dielectric material” generally refer to any type or number of non-electrically conductive materials. In some cases, dielectric material may be used to make up the structure of a package substrate. For example, dielectric material may be incorporated into an integrated circuit package as layers of laminate film or as a resin molded over integrated circuit dice mounted on the substrate.

The term “metallization” generally refers to metal layers formed on, over, and/or through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and may carry the same or similar meaning.

The term “bump” generally refers to a conductive layer or structure formed on a bond pad, which is typically made of solder or metal and has a round or curved shape, hence the term “bump”.

The term “substrate” generally refers to a planar platform comprising dielectric and/or metallization structures. A substrate may mechanically support and electrically couple one or more IC dies on a single platform, with encapsulation of the one or more IC dies by a moldable dielectric material. A substrate may include bumps or pads as bonding interconnects on one or both sides. For example, one side of the substrate, generally referred to as the “die side”, may include bumps or pads for chip or die bonding. The opposite side of the substrate, generally referred to as the “land side”, may include bumps or pads for bonding the package to a printed circuit board.

The term “assembly” generally refers to a grouping of parts into a single functional unit. For example, certain parts may be permanently bonded together, integrated together, and/or mechanically assembled (e.g., where parts may be removable) into a functional unit.

The terms “coupled” or “connected” means a direct or indirect connection, such as a direct electrical, mechanical, magnetic, or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

1. A microelectronic assembly, comprising:
a substrate comprising silicon;
complementary metal-oxide-semiconductor (CMOS) circuitry over the substrate; and
an integrated circuit (IC) die over the CMOS circuitry, wherein the IC die comprises one or more passive radio frequency (RF) components, and wherein the IC die has a thickness of 5 micrometers (μm) or less.

2. The microelectronic assembly of claim 1, wherein the one or more passive RF components include at least one of an antenna, an interconnect, an inductor, a capacitor, or a transformer.

3. The microelectronic assembly of claim 1, wherein:
the IC die is within a metal stack;
the IC die is on a metal stack; or
the IC die is between a plurality of interconnect bumps.

4. The microelectronic assembly of claim 1, wherein the IC die is electrically coupled to the CMOS circuitry via a hybrid-bonded interconnect.

5. The microelectronic assembly of claim 1, wherein the IC die has an area of less than 1 millimeter (mm)².

6. The microelectronic assembly of claim 1, further comprising a mesa structure under the IC die, wherein the mesa structure has a similar footprint as the IC die, and wherein the mesa structure comprises at least one of a dielectric material or a metal.

7. The microelectronic assembly of claim 1, further comprising a dummy die, wherein the dummy die has no electrical functionality.

8. The microelectronic assembly of claim 1, further comprising an RF transceiver, wherein the RF transceiver comprises the CMOS circuitry and the IC die.

9. An electronic device, comprising:
complementary metal-oxide-semiconductor (CMOS) circuitry; and
a plurality of integrated circuit (IC) components, wherein the plurality of IC components include one or more antennas, interconnects, inductors, capacitors, and transformers, wherein at least one of the IC components is comprised in an IC die, wherein the IC die is on an adhesive area having a similar footprint as the IC die.

10. The electronic device of claim 9, wherein the adhesive area comprises a mesa structure under the IC die, wherein the mesa structure has a similar footprint as the IC die, and wherein the mesa structure comprises at least one of a dielectric material or a metal.

11. The electronic device of claim 9, wherein the one or more interconnects include a terahertz waveguide network, wherein the terahertz waveguide network is comprised in the IC die.

12. The electronic device of claim 9, wherein the CMOS circuitry comprises one or more gate-all-around transistors.

13. The electronic device of claim 9, further comprising a radio frequency (RF) transceiver, wherein the RF transceiver comprises the CMOS circuitry and the plurality of IC components.

14. The electronic device of claim 13, wherein:
the electronic device further comprises a processing unit, wherein the processing unit is a central processing unit, a graphics processing unit, an application-specific integrated circuit, or a field-programmable gate array; and
the RF transceiver is to send and receive RF signals on behalf of the processing unit.

15. A method, comprising:
receiving a first substrate, wherein the first substrate comprises a release layer and a layer of integrated circuit (IC) components over the release layer, wherein the layer of IC components comprises one or more antennas, interconnects, inductors, capacitors, or transformers;
receiving a second substrate, wherein the second substrate comprises one or more adhesive areas;
partially bonding the first substrate to the second substrate, wherein one or more IC components on the first substrate are bonded to the one or more adhesive areas on the second substrate, wherein the one or more IC components are from the layer of IC components; and
separating the first substrate from the second substrate, wherein the one or more IC components are separated from the first substrate and remain on the second substrate.

16. The method of claim 15, wherein the second substrate further comprises complementary metal-oxide-semiconductor (CMOS) circuitry.

17. The method of claim 15, further comprising, before separating the first substrate from the second substrate:
exposing the release layer to electromagnetic radiation from a laser.

18. The method of claim 15, wherein the release layer comprises at least one of a metallic layer or a dielectric layer.

19. The method of claim 15, wherein the one or more adhesive areas include one or more raised structures, wherein the one or more raised structures comprise at least one of a dielectric material or a metal.

20. The method of claim 15, wherein receiving the first substrate comprises forming the first substrate, wherein forming the first substrate comprises:
receiving a base substrate;
forming the release layer over the base substrate;
forming or transferring the layer of IC components over the release layer; and
partially singulating the layer of IC components.
